(19) United States
(12) Patent Application Publication
(10) Pub. No.: US 2025/0017008 A1
(43) Pub. Date: Jan. 9, 2025

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: Kang Lib KIM, Suwon-si (KR); Sungsu MOON, Suwon-si (KR); Sea Hoon LEE, Suwon-si (KR); Junhee LIM, Suwon-si (KR); Seongpil CHANG, Suwon-si (KR)

(21) Appl. No.: 18/439,835

(22) Filed: Feb. 13, 2024

(30) Foreign Application Priority Data
Jul. 5, 2023 (KR) 10-2023-0087392

(51) Int. Cl. H10B 43/27; H01L 25/065; H10B 41/10; H10B 41/27; H10B 41/35; H10B 43/10; H10B 43/35; H10B 80/00

(52) U.S. Cl. CPC H10B 43/27; H01L 25/0652; H10B 41/10; H10B 41/27; H10B 41/35; H10B 43/10; H10B 43/35; H10B 80/00; H01L 2225/06506

(57) ABSTRACT

A semiconductor device includes a cell array region and a connection region. A gate stacking structure includes gate electrodes and interlayer insulation layers that are alternately stacked. The gate stacking structure extends in a first direction and is separated by separation structures in a second direction. A channel structure penetrates the gate stacking structure in the cell array region. Gate contact portions penetrate the gate stacking structure in the connection region. The gate contact portions are electrically connected to the gate electrodes, respectively. An insulation layer is provided separately from the separation structure and covers at least the gate stacking structure. The insulation layer comprises a base insulation portion and a hydrogen-containing insulation portion. The hydrogen-containing insulation portion includes a hydrogen-containing portion having a different material from a material of the base insulation portion. The hydrogen-containing portion including hydrogen.

### CROSS-REFERENCE TO RELATED APPLICATION

This application claims priority under 35 U.S.C. § 119 to Korean Patent Application No. 10-2023-0087392, filed on Jul. 5, 2023 in the Korean Intellectual Property Office, the disclosure of which is incorporated by reference in its entirety herein.

### 1. TECHNICAL FIELD

The present disclosure relates to a semiconductor device and an electronic system including the same.

### 2. DISCUSSION OF RELATED ART

In an electronic system including a data storage, a semiconductor device may be capable of storing high-capacity data. Accordingly, a method for increasing a data storage capacity of a semiconductor device is being actively researched. For example, a semiconductor device including three-dimensionally arranged memory cells instead of two-dimensionally arranged memory cells has been proposed to increase the data storage capacity of a semiconductor device.

### SUMMARY

An embodiment of the present disclosure provides a semiconductor device that can increase performance and productivity, and an electronic system including the same.

According to an embodiment of the present disclosure, a semiconductor device including a cell array region and a connection region. A gate stacking structure includes a plurality of gate electrodes and a plurality of interlayer insulation layers that are alternately stacked. The gate stacking structure extends in a first direction and is separated by a plurality of separation structures in a second direction that crosses the first direction. A channel structure penetrates the gate stacking structure in the cell array region. A plurality of gate contact portions penetrate the gate stacking structure in the connection region. The plurality of gate contact portions are electrically connected to the plurality of gate electrodes, respectively. An insulation layer is provided separately from the separation structure. The insulation layer covers at least the gate stacking structure. The insulation layer comprises a base insulation portion and a hydrogen-containing insulation portion. The hydrogen-containing insulation portion includes a hydrogen-containing portion having a different material from a material of the base insulation portion. The hydrogen-containing portion includes hydrogen.

According to an embodiment of the present disclosure, a semiconductor device including a cell array region and a connection region. A gate stacking structure includes a plurality of gate electrodes and a plurality of interlayer insulation layers that are alternately stacked. A channel structure penetrates the gate stacking structure in the cell array region. An insulation layer is disposed in the connection region and covers at least the gate stacking structure. The insulation layer comprises a hydrogen-containing insulation portion including a hydrogen-containing portion having a material that is different from an insulating material disposed in the cell array region. The hydrogen-containing portion contains hydrogen. A base insulation portion includes a material that is different from the material of the hydrogen-containing portion.

An electronic system according to an embodiment may include a main substrate, the above-stated semiconductor device disposed on the main substrate, and a controller electrically connected with the semiconductor device on the main substrate.

According to an embodiment of the present disclosure, an electronic system includes a main substrate. A semiconductor device is on the main substrate. A controller that is electrically connected with the semiconductor device is on the main substrate. The semiconductor device comprises a cell array region and a connection region. The semiconductor device comprises a gate stacking structure that includes a plurality of gate electrodes and a plurality of interlayer insulation layers that are alternately stacked. The gate stacking structure extends in a first direction and is separated by a plurality of separation structures in a second direction that crosses the first direction. A channel structure penetrates the gate stacking structure in the cell array region. A plurality of gate contact portions penetrates the gate stacking structure in the connection region. The plurality of gate contact portions are electrically connected to the plurality of gate electrodes, respectively. An insulation layer is provided separately from the separation structure. The insulation layer covers at least the gate stacking structure. The insulation layer comprises a base insulation portion and a hydrogen-containing insulation portion. The hydrogen-containing insulation portion includes a hydrogen-containing portion having a different material from a material of the base insulation portion. The hydrogen-containing portion includes hydrogen.

According to an embodiment, a hydrogen-containing insulation portion may be provided to supply hydrogen to a memory cell. As a result, cell properties may be increased by increasing a passivation property of the memory cell. In this case, the hydrogen-containing insulation portion is provided separately from the separation structure, and thus, a high degree of freedom in design and a sufficient size may be achieved. For example, the hydrogen-containing insulation portion is disposed in the connection region and not in the cell array region, and thus, a manufacturing process can be performed more easily and stability can be increased. In addition, the insulation layer can increase various properties by including a base insulation portion. Accordingly, performance of a semiconductor device can be effectively increased.

According to an embodiment, a semiconductor device having a hydrogen-containing insulation portion and having excellent performance can be formed through an easy process, and thus productivity of the semiconductor device can be increased.

### BRIEF DESCRIPTION OF THE DRAWINGS

FIG. 1 is a partial top plan view of a semiconductor device according to an embodiment of the present disclosure.

FIG. 2 is a partial cross-sectional view of FIG. 1, taken along the lines A1-A2, B1-B2, B3-B4, and C1-C2 according to an embodiment of the present disclosure.

FIG. 3 is a partial cross-sectional view of an example of a channel structure included in the semiconductor device shown in FIG. 1 according to an embodiment of the present disclosure.

FIG. 4A to FIG. 4H are partial cross-sectional views of a manufacturing method of a semiconductor device according to embodiments of the present disclosure.

FIG. 5 is provided for description of the upper support member which may be used in the manufacturing method of the semiconductor device according to an embodiment of the present disclosure.

FIG. 6 is a partial top plan view of a semiconductor device according to an embodiment of the present disclosure.

FIG. 7 is a partial top plan view of a semiconductor device according to an embodiment of the present disclosure.

FIG. 8 is a partial top plan view of a semiconductor device according to an embodiment of the present disclosure.

FIG. 9A to FIG. 9F are partial cross-sectional views of a manufacturing method of the semiconductor device shown in FIG. 8 according to embodiments of the present disclosure.

FIG. 10 is a schematic cross-sectional view of a semiconductor device according to an embodiment of the present disclosure.

FIG. 11 schematically illustrates an electronic system including a semiconductor device according to an embodiment of the present disclosure.

FIG. 12 schematically illustrates an electronic system including a semiconductor device according to an embodiment of the present disclosure.

FIG. 13 is a schematic cross-sectional view of a semiconductor package according to an embodiment of the present disclosure.

FIG. 14 is a schematic cross-sectional view of a semiconductor package according to an embodiment of the present disclosure.

### DETAILED DESCRIPTION OF EMBODIMENTS

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the described embodiments provided herein.

A portion unrelated to the description is omitted to clearly describe embodiments of the present disclosure, and the same or similar components are denoted by the same reference numeral throughout the present specification.

Further, since sizes and thicknesses of portions, regions, members, units, layers, films, etc. shown in the accompanying drawings may be arbitrarily shown for better understanding and ease of description, the present disclosure is not necessarily limited to the illustrated sizes and thicknesses. Thicknesses of some portions, regions, members, units, layers, films, etc. may be enlarged in the drawings for clarity purposes. In addition, in the drawings, thicknesses of portions, regions, members, units, layers, films, etc. may be exaggerated for convenience of explanation.

It will be understood that when a component such as a layer, film, region, or substrate is referred to as being “on” another component, it may be directly on other component or intervening components may also be present. In contrast, when a component is referred to as being “directly on” another component, there are no intervening components present. Further, when a component is referred to as being “on” or “above” a reference component, a component may be positioned on or below the reference component.

In addition, unless explicitly described to the contrary, the word “comprise”, “include”, or “contain”, and variations such as “comprises”, “comprising”, “includes”, “including”, “contains”, or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

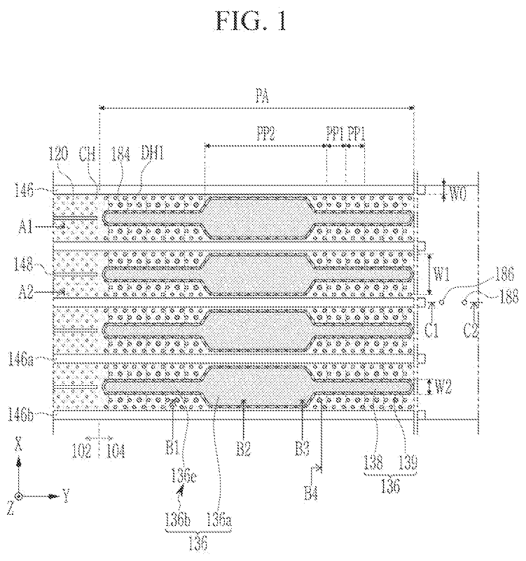

Hereinafter, referring to FIG. 1 to FIG. 3 and FIG. 4A to FIG. 4H, a semiconductor device and a manufacturing method according to embodiments of the present disclosure will be described.

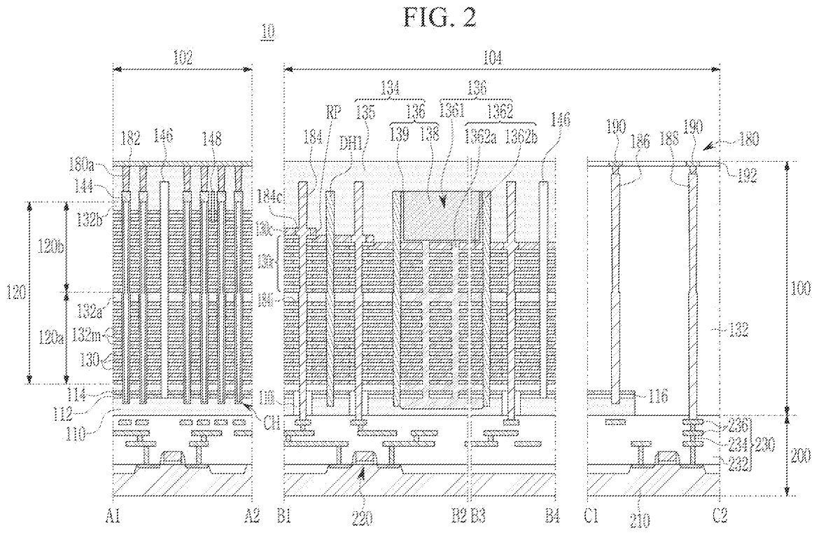

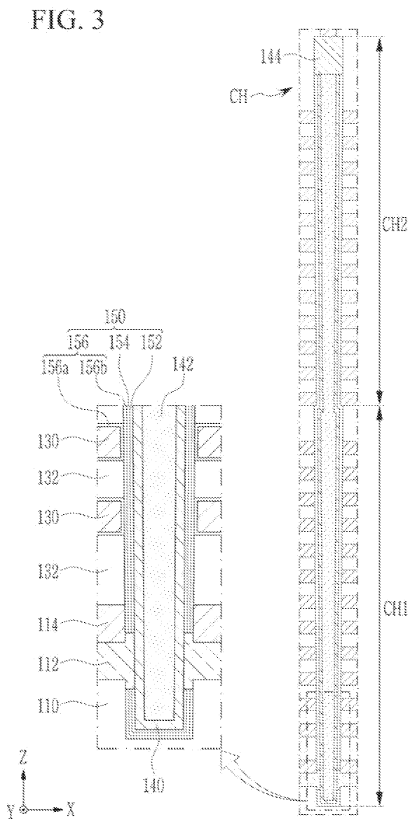

FIG. 1 is a partial top plan view of a semiconductor device according to an embodiment, and FIG. 2 is a partial cross-sectional view of FIG. 1, taken along the lines A1-A2, B1-B2, B3-B4, and C1-C2. FIG. 3 is a partial cross-sectional view of an example of a channel structure included in the semiconductor device shown in FIG. 1.

For simple illustration and clear understanding, a second wiring portion 180 is omitted and a top plan view of a channel structure CH and a gate contact portion 184 are shown in FIG. 1. In a connection region 104 of FIG. 1, the dotted line disposed in a second direction (e.g., the X-axis direction) schematically shows a boundary of pad portions PP1 and PP2.

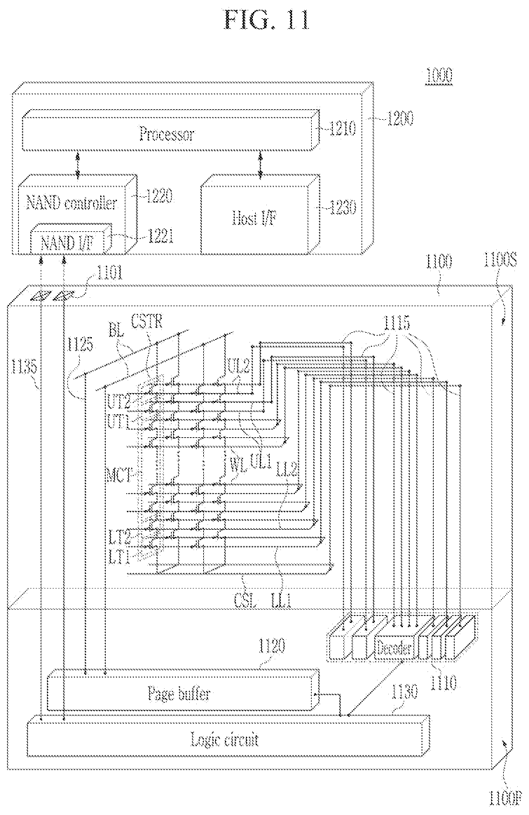

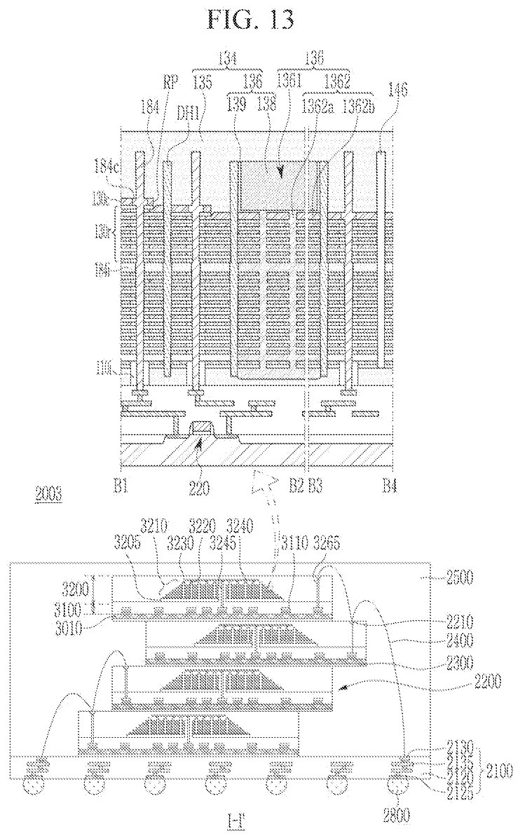

Referring to FIG. 1 to FIG. 3, a semiconductor device 10 according to an embodiment may include a cell region 100 provided with a memory cell structure and a circuit region 200 provided with a peripheral circuit structure controlling the memory cell structure. For example, in an embodiment, the circuit region 200 and the cell region 100 may be portions respectively corresponding to a first structure 1100F and a second structure 1100S of the semiconductor device 1100 included in an electronic system 1000 shown in FIG. 11. For example, the circuit region 200 and the cell region 100 may be portions respectively including the first structure 3100 and a second structure 3200 of a semiconductor chip 2200 shown in FIG. 13.

In an embodiment, the circuit region 200 may include a peripheral circuit structure formed on a first substrate 210, and the cell region 100 may be provided with a gate stacking structure 120 and a channel structure CH formed on a cell array region 102 on a second substrate 110, as a memory cell structure. In an embodiment, the circuit region 200 is provided with a first wiring portion 230 electrically connected with the peripheral circuit structure, and the cell region 100 may be provided with a second wiring portion 180 electrically connected with the memory cell structure.

In an embodiment, the cell region 100 may be positioned on (e.g., disposed directly thereon) the circuit region 200. Correspondingly, since it is not necessary to secure an area corresponding to the circuit region 200 separately from the cell region 100, the area of the semiconductor device 10 can be reduced. However, embodiments of the present disclosure are not necessarily limited thereto, and the circuit region 200 may be positioned next to the cell region 100 (e.g., in a horizontal direction) in some embodiments. Numerous other variations are possible.

In an embodiment, the circuit region 200 may include a first substrate 210, and a circuit element 220 and the first wiring portion 230 formed on the first substrate 210.

In an embodiment, the first substrate 210 may be a semiconductor substrate including a semiconductor material. For example, the first substrate 210 may be a semiconductor substrate formed of a semiconductor material, or may be a semiconductor substrate in which a semiconductor layer is formed on a base substrate. For example, in an embodiment, the first substrate 210 may be formed of single crystal or polysilicon, epitaxial silicon, germanium, silicon-germanium, silicon-on-insulator (SOI), or germanium-on-insulator (GOI), or the like. However, embodiments of the present disclosure are not necessarily limited thereto.

The circuit element 220 formed on the first substrate 210 may include any of various circuit elements that control operation of the memory cell structure provided in the cell region 100. For example, in an embodiment, the circuit element 220 may form a peripheral circuit structure such as a decoder circuit (refer to 1110 in FIG. 11), a page buffer (refer to 1120 in FIG. 11), a logic circuit (refer to 1130 in FIG. 11), or the like. The circuit element 220 may include, for example, a transistor. However, embodiments of the present disclosure are not necessarily limited thereto. For example, the circuit element 220 may include not only an active element such as a transistor or the like but also a passive element such as a capacitor, a resistor, an inductor, or the like.

In an embodiment, the first wiring portion 230 positioned on the first substrate 210 may be electrically connected with the circuit element 220. In an embodiment, the first wiring portion 230 may include a plurality of wiring layers 236 spaced apart from each other with a first insulation layer 232 therebetween and connected by a contact via 234 to form a preferred path. The wiring layer 236 or the contact via 234 may include any of various conductive materials, and the first insulation layer 232 may include any of various insulating materials.

The cell region 100 may include the cell array region 102 and a connection region 104. A gate stacking structure 120 and a channel structure CH may be formed on the second substrate 110 in the cell array region 102. A structure for connecting the gate stacking structure 120 and/or channel structure CH with the circuit region 200 formed in the cell array region 102 or an external circuit may be disposed in the connection region 104.

In an embodiment, the second substrate 110 may be a semiconductor substrate including a semiconductor material. For example, the second substrate 110 may be a semiconductor substrate formed of a semiconductor material, or may be a semiconductor substrate in which a semiconductor layer is formed on a base substrate. For example, in an embodiment, the second substrate 110 may be formed of silicon, germanium, silicon-germanium, a silicon-on-insulator, or a germanium-on-insulator. Here, the semiconductor material included in the second substrate 110 may be doped with a p-type or n-type impurity. For example, the n-type impurity (e.g., phosphorus (P), arsenic (As), or the like) may be doped. However, embodiments of the present disclosure are not necessarily limited thereto and the conductivity type and material of the impurity doped into the semiconductor material may vary.

In the cell array region 102, a gate stacking structure 120 including a cell insulation layer 132 and a gate electrode 130 that are alternately stacked on a first side (e.g., a front surface or top surface) of the second substrate 110, and a channel structure CH including a portion that extends in a cross-direction (e.g., a vertical direction that is perpendicular to the second direction 110 such as the Z-axis direction) that crosses the second substrate 110 while penetrating the gate stacking structure 120 may be formed.

In an embodiment, first and second horizontal conductive layers 112 and 114 may be provided between the second substrate 110 and the second substrate 110 in the cell array region 102. The first and second horizontal conductive layers 112 and 114 may serve to electrically connect the channel structure CH and the second substrate 110. For example, the horizontal conductive layers 112 and 114 may include a first horizontal conductive layer 112 disposed on the first side of the second substrate 110, and may further include a second horizontal conductive layer 114 disposed on the first horizontal conductive layer 112. In some regions of the connection region 104, a horizontal insulation layer 116 may be provided between the second substrate 110 and the gate stacking structure 120 and the first horizontal conductive layer 112 may not be included in these regions. In a manufacturing process, some of the horizontal insulation layer 116 may be replaced with the first horizontal conductive layer 112, but another portion of the horizontal insulation layer 116 disposed in the connection region 104 may remain in the connection region 104. In an embodiment, the horizontal insulation layer 116 may be formed of a single layer or may include a plurality of layers. In some embodiments, an oxide layer may be further provided on upper and lower portions of the horizontal insulation layer 116. However, embodiments of the present disclosure are not necessarily limited thereto.

In an embodiment, the first horizontal conductive layer 112 may function as a portion of a common source line of the semiconductor device 10. For example, the first horizontal conductive layer 112 and the second substrate 110 may serve as a common source line. As shown in the enlarged view of FIG. 3, the channel structure CH extends to reach the second substrate 110 by penetrating (e.g., in the Z direction) the first and second horizontal conductive layers 112 and 114, and may be directly connected with the channel layer 140 of the first horizontal layer 112 in a portion where the first horizontal conductive layer 112 is located.

In an embodiment, the first and second horizontal conductive layers 112 and 114 may include a semiconductor material (e.g., polysilicon). For example, the first horizontal conductive layer 112 may be a polysilicon layer doped with an impurity, and the second horizontal conductive layer 114 may be a polysilicon layer doped with an impurity or a layer including an impurity diffused from the first horizontal conductive layer 112. However, embodiments of the present disclosure are not necessarily limited thereto and the second horizontal conductive layer 114 may be formed of an insulating material in some embodiments. In some embodiments, the second horizontal conductive layer 114 may not be provided separately.

The gate stacking structure 120 may be formed by alternatively stacking a plurality of cell insulation layers 132 and a plurality of gate electrode 130 on the second substrate 110 (e.g., on the first and second horizontal conductive layers 112 and 114 on the second substrate 110).

In an embodiment, the cell insulation layer 132 may include an interlayer insulation layer 132m disposed below the gate electrode 130 or between two adjacent gate electrodes 130 in the gate stacking structure 120 and upper insulation layers 132a and 132b that are disposed at an upper portion of the respective gate stacking structures 120. In an embodiment, a thickness (e.g., length in the Z direction) of each of the plurality of cell insulation layers 132 may not all be the same as each other. For example, in an embodiment, thicknesses of the upper insulation layers 132a and 132b may be greater than a thickness of the interlayer insulation layer 132m. Here, an upper insulation layer (e.g., a first upper insulation layer 132a) among the upper insulation layers 132a and 132b in a gate stacking structure (e.g., a first gate stack structure 120a) disposed below or in a middle is disposed between two gate electrodes 130, and therefore, the upper insulation layer (e.g., the first upper insulation layer 132a) may be one of the interlayer insulation layers 132m.

In an embodiment, the cell insulation layer 132 may include an insulation layer 134 in the connection region 104. For example, in an embodiment, the cell insulation layer 132 may include the insulation layer 134 in a portion where a gate contact portion 184 is provided in the connection region 104. The insulation layer 134 refers to an insulation layer disposed in the connection region 104 (e.g., the portion where the gate contact portion 184 is located in the connection region 104) of the cell insulation layer 132 for clear understanding and better explanation.

In an embodiment, at least a portion of the insulation layer 134 may be formed as a separate insulation layer from the interlayer insulation layer 132m, the upper insulation layer 132a and 132b in the cell array region 102. In some embodiments, at least a portion of the insulation layer 134 may include a portion of the same material as the interlayer insulation layer 132m, the upper insulation layers 132a and 132b in the cell array region 102, or manufactured through the same manufacturing process as the interlayer insulation layer 132m, the upper insulation layers 132a and 132b in the cell array region 102.

In an embodiment, at least a portion of the insulation layer 134 may be formed of a separate insulation layer from the cell insulation layer 132 at a portion where a source contact portion 186 and/or a through plug 188 are positioned in the connection region 104. In some embodiments, at least a portion of the insulation layer 134 may include a portion of the same material as the cell insulation layer 132 at the portion where the source contact portion 186 and/or the through plug 188 are disposed, or may include the same layer manufactured through the same manufacturing process as the cell insulation layer 132 disposed at the portion where the source contact portion 186 and/or the through plug 188 are disposed.

For convenience of illustration, in the drawing, the cell insulation layer 132 is provided as one without a boundary at the portion where the source contact portion 186 and/or the through plug 188 are positioned in the connection region 104. However, in the connection region 104, the cell insulation layer 132 may have a structure including one or a plurality of insulation layers in a portion where the source contact portion 186 and/or the through plug 188 are disposed. However, embodiments of the present disclosure are not necessarily limited thereto. In FIG. 2, it is illustrated as an example that a hydrogen-containing insulation portion 136 or an insulation layer 134 is positioned in the portion where the gate contact portion 184 is located in the connection region 104, but, depending on embodiments, the hydrogen-containing insulation portion 136 may be positioned in a portion where the source contact portion 186 and/or the through plug 188 are disposed. As such, the shape and structure of the cell insulation layer 132 may be variously modified depending in some embodiments.

In an embodiment, the gate electrode 130 may include any of various conductive materials. For example, the gate electrode 130 may include a metal material such as tungsten (W), copper (Cu), aluminum (Al), or the like, polysilicon, a metal nitride (e.g., titanium nitride (TiN), tantalum nitride (TaN), etc.), or a combination thereof. As shown in the enlarged view of FIG. 3, a blocking layer 156 (e.g., a first blocking layer 156a) formed of an insulating material may be disposed at an outer side of the gate electrode 130.

The cell insulation layer 132 disposed in a portion where the source contact portion 186 and/or the through plug 188 is disposed or in the cell array region 132 in the connection region 104 may include any of various insulating materials. For example, in an embodiment, the cell insulation layer 132 disposed in the portion where the source contact portion 186 and/or the through plug 188 is disposed or in the cell array region 132 in connection region 104 may include a silicon oxide, a silicon nitride, a silicon oxynitride, and a low dielectric constant material having lower permittivity than silicon oxide, or a combination thereof. The insulation layer 134 disposed in the connection region 104 may include a base insulation portion 135 and a hydrogen-containing insulation portion 136, and this will be described in more detail later.

In an embodiment, a channel structure CH that penetrates the gate stacking structure 120 and extends in a direction that crosses the second substrate 110 (e.g., a vertical direction that is perpendicular to the second substrate 110, such as the Z-axis direction) may be formed.

In an embodiment, the channel structure CH may include a channel layer 140, and a gate dielectric layer 150 disposed on the channel 140 between the gate electrode 130 and the channel layer 140. The channel structure CH may further include a core insulation layer 142 disposed inside the channel layer 140. However, embodiments of the present disclosure are not necessarily limited thereto. For example, in an embodiment, the core insulation layer 142 may not be provided. The channel structure CH may further include a channel pad 144 disposed on the channel layer 140 and/or the gate dielectric layer 150. In an embodiment, the gate dielectric layer 150 disposed between the gate electrode 130 and the channel layer 140 may include a tunneling layer 152, a charge storage layer 154, and a blocking layer 156 that are sequentially formed on the channel layer 140.

In an embodiment, each channel structure CH forms one memory cell string, and a plurality of channel structures CH may be spaced apart from each other while forming rows and columns on a plane. For example, the plurality of channel structures CH may be disposed in any of various forms such as a lattice form and a zigzag form on a plane. The channel structure CH may have a column shape. For example, on a cross-section, the channel structure CH may have an inclined surface having a width that becomes narrower as it approaches the second substrate 110 according to the aspect ratio. However, embodiments of the present disclosure are not necessarily limited thereto, and the arrangement, structure, and shape of the channel structure CH may be variously modified.

In an embodiment, the channel layer 140 may include a semiconductor material, for example, polysilicon. The core insulation layer 142 may include any of various insulating materials. For example, in an embodiment the core insulation layer 142 may include a silicon oxide, a silicon nitride, a silicon oxynitride, or a combination thereof.

In an embodiment, the tunneling layer 152 may include an insulating material (e.g., silicon oxide, silicon oxynitride, etc.) capable of charge tunneling. For example, the charge storage layer 154 may be used as a data storage region, and may include polysilicon, a silicon nitride, or the like. The blocking layer 156 may include an insulating material that can prevent an undesirable charge inflow into the gate electrode 130. For example, in an embodiment, the blocking layer 156 may include a silicon oxide, a silicon nitride, a silicon oxide, a high dielectric constant material having a higher permittivity than silicon oxide, or a combination thereof. In an embodiment, the blocking layer 156 may include a first blocking layer 156a including a portion extending in parallel with the gate electrode 130, and a second blocking layer 156b extending vertically between the first blocking layer 156a and the charge storage layer 154.

However, a material and a stacking structure of the channel layer 140, the core insulation layer 142, and the gate dielectric layer 150 may be variously modified, and embodiments of the present disclosure are not necessarily limited thereto.

The channel pad 144 may be disposed to cover an upper surface of the core insulation layer 142 and electrically connected with the channel layer 140. In an embodiment, the channel pad 144 may include a conductive material, for example, impurity-doped polysilicon. However, embodiments of the present disclosure are not necessarily limited thereto.

In an embodiment, the gate stacking structure 120 may include a plurality of gate stacking structures 120a and 120b that are sequentially stacked on the second substrate 110 (e.g., in the Z direction), and the channel structure CH may include a plurality of channel structures CH1 and CH2 that penetrate the plurality of gate stacking structures 120a and 120b (e.g., in the Z direction). Thus, the number of stacked gate electrodes 130 can be increased, thereby increasing the number of memory cells with a stable structure. In the drawing, it is illustrated as an example that the gate stacking structure 120 includes a first gate stacking structure 120a and a second gate stacking structure 120b, but embodiments of the present disclosure are not necessarily limited thereto. Accordingly, in some embodiments the gate stacking structure 120 may be formed of a single gate stacking structure, or may include three or more gate stacking structures.

The plurality of channel structures CH1 and CH2 forming one channel structure CH may have a form connected to each other. In an embodiment, the plurality of channel structures CH1 and CH2 each has an inclined surface having a width that becomes narrower as it approaches the second substrate 110 according to the aspect ratio on a cross-section, and a connection portion of the plurality of channel structures CH1 and CH2 may be provided with a bent portion due to a width difference. As another example, the plurality of channel structures CH1 and CH2 may have inclined surfaces continuously connected without bending. In FIG. 3, it is illustrated as an example that the gate dielectric layer 150, the channel layer 140, and the core insulation layer 142 of the plurality of channel structures CH1 and CH2 extend together with each other, thereby forming an integral structure. However, embodiments of the present disclosure are not necessarily limited thereto, and the gate dielectric layer 150, the channel layer 140, and the core insulation layer 142 of the plurality of channel structures CH1 and CH2 may be separately formed and thus may be electrically connected with each other. In addition, a separate channel pad may be additionally provided at a connection portion of the plurality of channel structures CH1 and CH2. As described, the embodiment is not necessarily limited to the shape of the plurality of channel structures CH1 and CH2.

In an embodiment, the gate stacking structure 120 may be partitioned into plurality by a separation structure 146 that extends in a cross direction (e.g., vertical direction, such as the Z-axis direction) that crosses the second substrate 110 and penetrates the gate stacking structure 120. In addition, an upper separation region 148 may be formed in an upper portion of the gate stacking structure 120. On a plane, the separation structure 146 and/or the upper separation region 148 may be provided in plurality to extend in a first direction (e.g., the Y-axis direction) and spaced apart from each other at a predetermined interval in a second direction (e.g., the X-axis direction) that crosses the first direction.

By the separation structure 146, on a plane, a plurality of gate stacking structures 120 each extends in the first direction (e.g., the Y-axis direction) and may be spaced apart from each other at a predetermined interval in the second direction (e.g., the X-axis direction). The gate stacking structure 120 partitioned by the separation structure 146 may form one memory cell block. However, embodiments of the present disclosure are not necessarily limited thereto, and the range of memory cell block is not necessarily limited thereto.

For example, the separation structure 146 may pass through the gate stacking structure 120 (e.g., in the Z direction) and extend to the second substrate 110, and the upper separation region 148 may separate one or a portion of the plurality of gate electrodes 130 from each other. The upper separation region 148 may be disposed between the separation structures 146.

For example, in an embodiment, the separation structure 146 has an inclined surface having a width that gradually decreases towards the second substrate 110 when viewed on a cross-section due to a high aspect ratio. However, embodiments of the present disclosure are not necessarily limited thereto. A side surface of the separation structure 146 may be perpendicular to the second substrate 110 or may have a bent portion at a connection portion of the plurality of gate stacking structures 120a and 120b.

The separation structure 146 or the upper separation region 148 may be filled with any of various insulating materials. For example, in an embodiment, the separation structure 146 or the upper separation region 148 may include an insulating material such as a silicon oxide, a silicon nitride, or a silicon oxynitride. However, embodiments of the present disclosure are not necessarily limited thereto, and the structure, shape, and material of the separation structure 146 or upper separation region 148 may be variously modified.

In an embodiment, a connection region 104 and a second wiring portion 180 may be provided to connect the gate stacking structure 120 and the channel structure CH provided in the cell array region 102 to the circuit region 200 or an external circuit. The connection region 104 may be disposed at the periphery of the cell array region 102, and a portion of the second wiring portion 180 may be disposed.

Here, the second wiring portion 180 may include all members electrically connecting the gate electrode 130, the channel structure CH, the horizontal conductive layers 112 and 114, and/or the second substrate 110 to the circuit region 200 or an external circuit. For example, the second wiring portion 180 may include a bit line 182, a gate contact portion 184, a source contact portion 186, a through plug 188, and a contact via 180a connected to them, and a connection wire 190 that connects them.

The bit line 182 may be disposed on the cell insulation layer 132 of the gate stacking structure 120 formed in the cell array region 102. The bit line 182 may extend in the second direction (e.g., the X-axis direction) crossing the first direction in which the gate electrode 130 extends. The bit line 182 may be electrically connected to the channel structure CH, for example, the channel pad 144 through the contact via 180a, for example, a bit line contact via.

In an embodiment, the plurality of gate electrodes 130 may extend in, and be disposed in, the connection region 104 in the first direction (e.g., the Y-axis direction), and an extension length of the plurality of gate electrodes 130 in the connection region 104 may become sequentially less as a distance from the second substrate 110 increases. For example, the plurality of gate electrodes 130 may be disposed while having a stair shape in the connection region 104. In this embodiment, the plurality of gate electrodes 130 may have a stair shape in one direction or a plurality of directions. In the connection region 104, the plurality of gate contact portions 184 may be electrically connected to the plurality of gate electrodes 130 penetrating the cell insulation layer 132 and extending to the connection region 104.

In addition, one or a plurality of pad areas PA to which the gate contact portion 184 and the gate electrode 130 are connected may be provided in the connection region 104. For example, in an embodiment, each of the plurality of gate stacking structures 120a and 120b may be provided with one or a plurality of pad areas PA.

In an embodiment, in the pad area PA, the plurality of gate electrodes 130 may be sequentially removed by a recess portion RP. Accordingly, the plurality of pad portions, such as first and second pad portions PP1 and PP2, of the plurality of connection gate electrodes 130c to which each of the plurality of gate contact portion 184 is connected may be exposed upwardly.

In an embodiment, a plurality of pad portions provided in one pad area PA may include a first pad portion PP1 and a second pad portion PP2, each having a different length in the first direction (e.g., the Y-axis direction). The first pad portion PP1 may have a first length, which is relatively short in the first direction. The second pad portion PP2 may have a second length, which is longer than the first length in the first direction. Such a second pad portion PP2 may be formed in consideration of the arrangement of the first wiring portion 230 and a manufacturing process of the semiconductor device 10. In an embodiment, the second pad portion PP2 may be periodically disposed while disposing a plurality of first pad portions PP1 therebetween. However, embodiments of the present disclosure are not necessarily limited thereto.

In an embodiment, each gate contact portion 184 may penetrate the gate stacking structure 120 or the like in the connection region 104 and thus may be electrically connected to the circuit region 200. In this embodiment, the gate contact portion 184 is electrically connected to a connection gate electrode 130c provided with the first and second pad portions PP1 and PP2 among the plurality of gate electrodes 130 included in the gate stacking structure 120, and may be insulated from the other gate electrodes 130r, while disposing an insulation pattern 184i therebetween. In an embodiment, the first and second pad portions PP1 and PP2 may be disposed at an end of the connection gate electrode 130c, which is far away from the cell array region 102, and may have a larger thickness than other portions. The gate contact portion 184 may be connected to inner surfaces of the first and second pad portions PP1 and PP2 of the connection gate electrode 130c while penetrating the first and second pad portions PP1 and PP2. For example, the gate contact portion 184 may be protruded to inner surfaces of the first and second pad portions PP1 and PP2 to have a connection portion 184c that directly contacts the pad portions PP1 and PP2. A width of the insulation pattern 184i in the horizontal direction may be greater than a thickness of the remaining gate electrodes 130r in the vertical direction or thickness direction. Accordingly, the remaining gate electrode 130r and the gate contact portion 184 can be effectively insulated. However, embodiments of the present disclosure are not necessarily limited thereto.

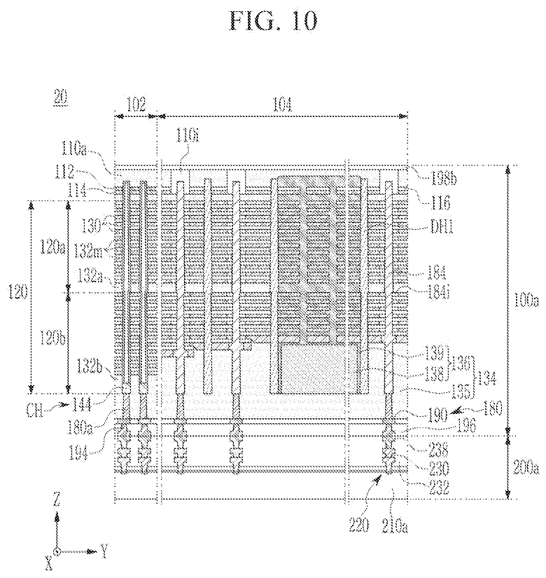

The gate contact portion 184 may penetrate the gate stacking structure 120 or the like and extend to a pad portion provided in the uppermost portion of the plurality of wiring layer 236 of the circuit region 200, thereby being connected to the pad portion. Accordingly, it is possible to increase the design freedom of the second wiring portion 180 by being connected to the circuit region 200 without passing through the connection wiring 190 or the like. However, a connection method between the gate contact portion 184 and the circuit region 200 may be variously modified. As another example, as shown in FIG. 10, the gate contact portion 184 may be connected to a circuit region (reference numeral 200a of FIG. 10) through the connection wiring 190 and a second bonding structure 194. This will be described later in detail with reference to FIG. 10. In an embodiment, the gate contact portion 184 may include a conductive material, and may include, for example, tungsten (W), copper (Cu), aluminum (Al), or the like, and may further include a diffusion barrier layer. However, embodiments of the present disclosure are not necessarily limited thereto and the material of the gate contact portion 184 may vary.

In the drawing and the above description, it is described as an example that the gate contact portion 184 is electrically connected to the circuit region 200 by penetrating the gate stacking structure 120. However, embodiments of the present disclosure are not necessarily limited thereto, and the gate contact portion 184 may be disposed to connect an upper portion of the gate electrode 130 and the connection wire 190. Other variations are also possible.

In addition, in the connection region 104, the source contact portion 186 penetrates the cell insulation layer 132 (e.g., in the Z direction) and thus is electrically connected with the first and second horizontal conductive layers 112 and 114 and/or the second substrate 110, and the through plug 188 may penetrate (e.g., in the Z direction) the gate stacking structure 120 or may be disposed in an outer side of the gate stacking structure 120 and thus may be electrically connected to the first wiring portion 230 of the circuit region 200.

The connection wire 190 may be disposed in the cell array region 102 and/or the connection region 104. The bit line 182, the gate contact portion 184, the source contact portion 186, and/or the through plug 188 may be electrically connected to the connection wire 190. For example, the gate contact portion 184, the source contact portion 186, and/or the through plug 188 may be connected to the connection wire 190 through the contact via 180a.

In FIG. 2, it is illustrated as an example that the connection wire 190 is provided as a single layer positioned on the same plane as the bit line 182 (e.g., in the Z direction), and the second insulation layer 192 is positioned in a portion other than the second wiring portion 180. However, this is briefly illustration for convenience in description and embodiments of the present disclosure are not necessarily limited thereto. For example, in some embodiments the connection wire 190 may include the plurality of wiring layers for electrical connection with the bit line 182, the gate contact portion 184, the source contact portion 186, and/or the through plug 188, and may further include the contact via.

As described, by the second wiring portion 180 and the first wiring portion 230, the bit line 182, the gate electrode 130, the horizontal conductive layers 112 and 114, and/or the second substrate 110 connected to the channel structure CH may be electrically connected to the circuit element 220 of the circuit region 200.

In FIG. 2, it is illustrated as an example that the gate contact portion 184, the source contact portion 186, and/or the through plug 188 each has an inclined side surface having a width that becomes narrower as it becomes closer to the second substrate 110 according to an aspect ratio on a cross-section, and a bent portion is provided at a boundary portion of the plurality of gate stacking structures 120a and 120b. However, embodiments of the present disclosure are not necessarily limited thereto. For example, in some embodiments the gate contact portion 184, the source contact portion 186, and/or the through plug 188 are not provided with a bent portion at a boundary portion of the plurality of gate stacking structures 120a and 120b. Numerous other variations are possible.

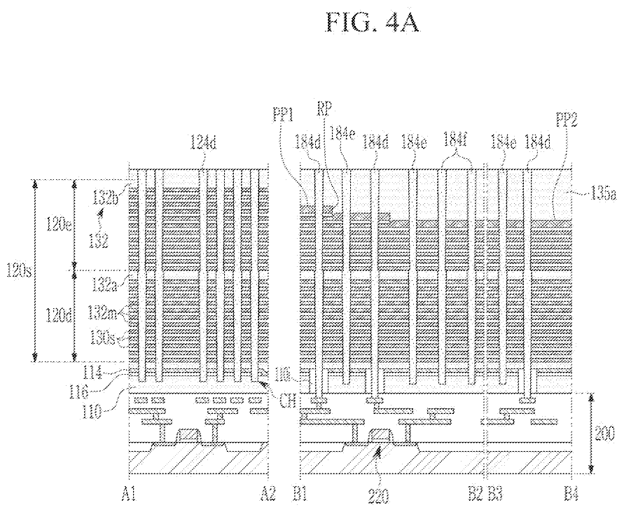

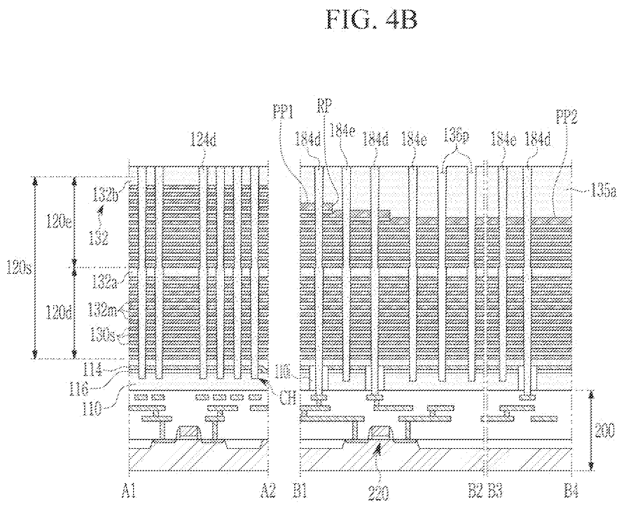

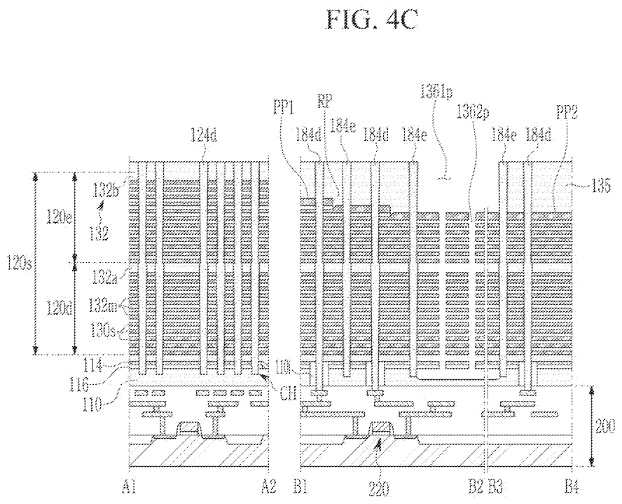

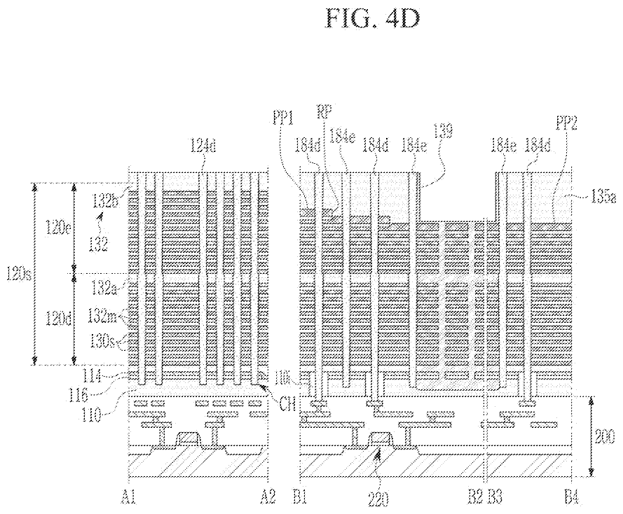

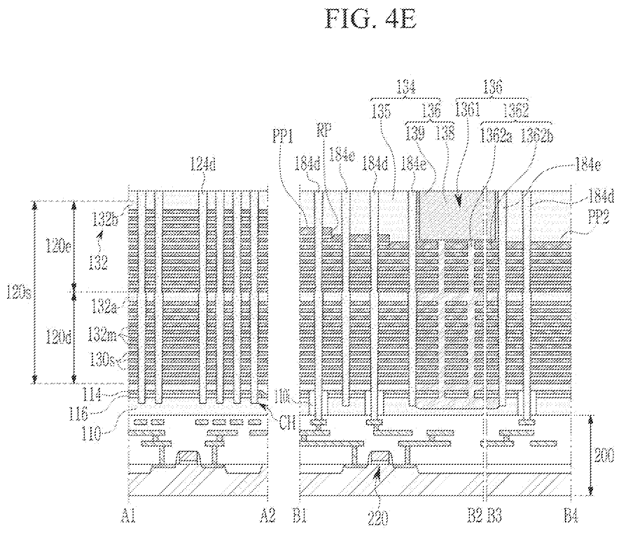

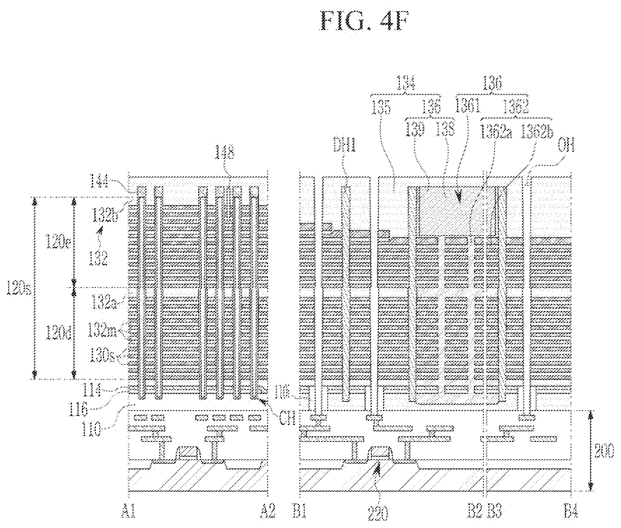

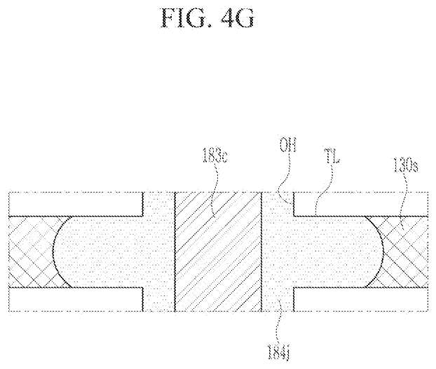

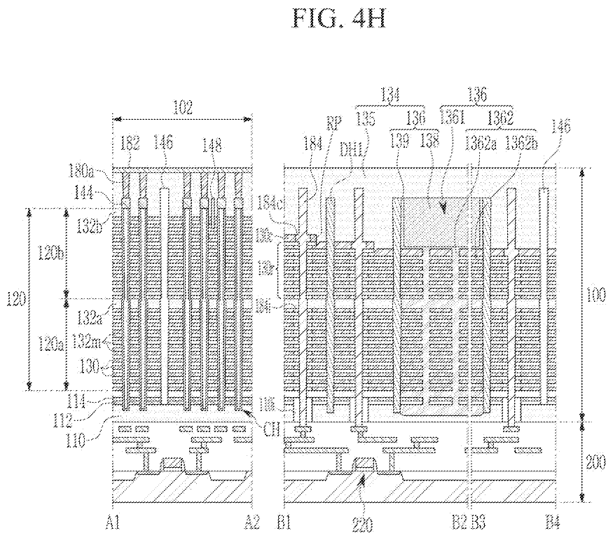

In an embodiment, a dummy structure DH1 passing through (e.g., in the Z direction) the insulation layer 134 and the gate stacking structure 120 positioned in the connection region 104 may be further provided. The dummy structure DH1 may serve to release stress that may be applied to the gate stacking structure 120. In an embodiment, the dummy structure DH1 may have the same or similar structure or shape as the channel structure CH, but is not electrically connected to the bit line 182. In an embodiment, the dummy structure DH1 may be formed together with the channel structure CH in the same process and formed of the same structure, shape, material, or the like, or formed in a process separate from the channel structure CH to have a different structure, shape, material, or the like. In an embodiment, the dummy structure DH1 may have a larger plane size than the channel structure CH. In the drawing, it is illustrated as an example that a plurality of dummy structure DH1 and/or a second dummy sacrificial layer (refer to 184f in FIG. 4A) is disposed to form a polygon shape (for example, a hexagonal shape), and disposed inside the gate electrode 130. However, embodiments of the present disclosure are not necessarily limited thereto and the shape, position, arrangement, number, or the like of the dummy structure DH1 and/or the second dummy sacrificial layer 184f may vary. For example, in an embodiment, at least a portion of the dummy structure DH1 may be disposed over or across an edge of the gate electrode 130 (e.g., disposed at an outer portion of the gate electrode 130) and formed in direct contact with the separation structure 146. Numerous other variations are possible.

For example, in an embodiment, when viewed in a cross-section, the dummy structure DH1 has an inclined side surface having a width that narrows as it approaches the second substrate 110 according to the aspect ratio, and may be provided with a bent portion due to a width difference at a boundary portion of the plurality of gate stacking structures 120a and 120b. However, embodiments of the present disclosure are not necessarily limited thereto. Therefore, the dummy structure DH1 may have a plane that is vertical to the second substrate 110, or the dummy structure DH1 may have an inclined side surface continuously connected without a bent portion in some embodiments.

In an embodiment, the insulation layer 134 may be disposed while covering at least the gate stacking structure 120 in the connection region 104. In an embodiment, the insulation layer 134 may include an interlayer insulation layer 132m or a horizontal portion 1362b disposed between a portion disposed on the gate stacking structure 120 and the plurality of gate electrodes 130 included in the gate stacking structure 120. The insulation layer 134 may be a member provided separately from the separation structure 146. For example, in an embodiment, the insulation layer 134 may be formed by a process different from that of the separation structure 146, and may include an insulating material different from that of the separation structure 146 or a material not included in the separation structure 146.

In an embodiment, the insulation layer 134 may include a hydrogen-containing insulation portion 136 including a hydrogen-containing portion 138. In an embodiment, the hydrogen-containing insulation portion 136 forms a portion of the insulation layer 134 disposed in the connection region 104, and a base insulation portion 135 formed of a different material may be further included in the insulation layer 134.

In an embodiment, the hydrogen-containing insulation portion 136 may include a portion (e.g., hydrogen-containing portion 138) formed of a material that is different from the insulation material disposed in the cell array region 102. For example, the hydrogen-containing insulation portion 136 may include the interlayer insulation layer 132m disposed in the cell array region 102, upper insulation layers 132a and 132b, and/or a portion formed of a material different from the insulating material contained in the separation structure 146. The hydrogen-containing insulation portion 136 may include a portion (e.g., hydrogen-containing portion 138) formed of a material different from the insulating material (e.g., base insulation portion 135) disposed in the connection region 104.

In the present specification, in an embodiment, in which the hydrogen-containing portion 138 is formed of a material different from the insulating material in the cell array region 102 and the insulating material included in the base insulation portion 135, it may include not only a case that the hydrogen-containing portion 138 is formed of a material different from the insulating material but also a case that the hydrogen-containing portion 138 is formed by a process different from or separated from a process of the insulating material and has a higher hydrogen content than the insulating material.

For example, the base insulation portion 135 may be an insulation portion formed of a base insulation layer (refer to 135a in FIG. 4A) formed in the connection region 104. The base insulation portion 135 or the base insulation layer 135a may be formed of the same material as at least a portion of the insulating material disposed in the cell array region 102. For example, the base insulation portion 135 or the base insulation layer 135a may be formed of the same material as at least a portion of the insulating material included in the interlayer insulation layer 132m, the upper insulation layers 132a and 132b, and the separation structure 146. For example, in an embodiment the base insulation portion 135 may be formed by the same formation process as the cell insulation layer 132 disposed in the cell array region 102.

In an embodiment, the hydrogen-containing insulation portion 136 may be an insulation portion formed by filling a hydrogen-containing material in at least a portion of the base insulation layer 135a after removing a portion of the base insulation layer 135a using an etching process or the like.

In an embodiment, the hydrogen-containing insulation portion 136 may further include a hydrogen-containing portion 138 containing hydrogen, and a barrier portion 139 formed of a material different from that of the hydrogen-containing portion 138.

In an embodiment, the hydrogen-containing insulation portion 136 or the hydrogen-containing portion 138, which contains hydrogen, may serve to provide hydrogen to a memory cell in the cell array region 102. For example, in an embodiment the hydrogen-containing portion 138 may serve to provide hydrogen to the memory cell through hydrogen diffusion in a subsequent heat treatment process. Hydrogen provided to the memory cell may increase the passivation properties by removing the dangling bonds of the memory cell. Accordingly, the cell property can be increased.

In an embodiment, a subsequent heat treatment process for diffusion of hydrogen contained in the hydrogen-containing portion 138 may be performed by any of various heat treatment processes performed in the manufacturing method of the semiconductor device 10 after forming the insulation layer 134. For example, hydrogen diffusion may be performed together in any of various heat treatments included in the manufacturing method of the semiconductor device 10. For example, the hydrogen diffusion may be carried out in the heat treatment process for crystallization of the channel layer 140 included in the channel structure CH. Hydrogen may then be provided to the memory cell without an additional process. Accordingly, the manufacturing process may be simplified and undesirable property changes in other portions (e.g., the circuit region 200) due to the separate heat treatment process can be prevented. However, embodiments of the present disclosure are not necessarily limited thereto, and hydrogen contained in the hydrogen-containing portion 138 may be diffused in any of various heat treatment processes.

For reference, in the conventional structure or manufacturing process, there is a certain limit to increasing the amount of hydrogen implantation of memory cells. For example, when an atomic layer deposition (ALD) is used to form the memory cell, there may be limitations in increasing the amount of hydrogen implant due to various restrictions related to the catalyst gas environment and the manufacturing process. When the number of memory cells or the density of memory cells increases, there may be a shortage of hydrogen in the memory cells. In addition, when an additional heat treatment is added to implant hydrogen, there is a temperature limit to prevent a change in the properties of the transistor included in the circuit region. Accordingly, when the number of memory cells or the density of the memory cells increases, the additional heat treatment may not be suitable for providing a sufficient amount of hydrogen to the memory cells.

In an embodiment, the hydrogen-containing insulation portion 136 is disposed in the connection region 104 where the channel structure CH is not provided, and thus the property of the memory cell can be increased without adding a separate space, while not changing a peripheral property of the channel structure CH. In addition, the hydrogen-containing insulation portion 136 is disposed in the connection region 104 at a portion where the gate contact portion 184 is disposed, and thus, the hydrogen-containing insulation portion 136 may be located in a portion adjacent to the gate stacking structure 120. Accordingly, hydrogen can be more effectively provided to the memory cell.

In an embodiment, the barrier portion 139 may be disposed between the hydrogen-containing portion 138 and the base insulation portion 135, the gate electrode 130, and/or the gate contact portion 184. Accordingly, the hydrogen-containing portion 138 may not directly contact the base insulation portion 135, the gate electrode 130, and/or the gate contact portion 184. Accordingly, a problem that may occur when the hydrogen-containing portion 138 directly contacts the base insulation portion 135, the gate electrode 130, and/or the gate contact portion 184 may be prevented from occurring. In an embodiment, the barrier portion 139 may have a thickness that is less than a thickness of the hydrogen-containing portion 138. However, embodiments of the present disclosure are not necessarily limited thereto and the barrier portion 139 may have a thickness equal to or larger than the thickness of the hydrogen-containing portion 138 in some embodiments.

In an embodiment, the base insulation portion 135 may have a different material and/or different properties than the hydrogen-containing insulation portion 136 (e.g., the hydrogen-containing portion 138). As described, the insulation layer 134 includes the base insulation portion 135 and the hydrogen-containing insulation portion 136 together to increase various properties.

For example, the base insulation portion 135 may include an insulating material that has excellent insulation properties and stability and can be manufactured or etched by an easy manufacturing process. The hydrogen-containing portion 138 may include an insulating material suitable for containing hydrogen.

For example, different stresses may be applied to the base insulation portion 135 and the hydrogen-containing portion 138. For example, in an embodiment the base insulation portion 135 may include an insulating material to which compressive stress is applied, and the hydrogen-containing portion 138 may include an insulating material to which tensile stress is applied. Since compressive stress and tensile stress are compensated for each other, stress applied to the insulation layer 134 can be reduced.

In an embodiment, the base insulation portion 135 may include a silicon oxide, a silicon oxynitride, a low dielectric constant material having lower permittivity than silicon oxide, or a combination thereof. In addition, the hydrogen-containing portion 138 may include a silicon nitride containing hydrogen. The hydrogen-containing portion 138 may contain hydrogen in a higher content than that of the base insulation portion 135, the barrier portion 139, and/or the separation structure 146. Silicon nitride is a material suitable for containing a relatively large amount of hydrogen compared to silicon oxide, or the like, and is a material that does not significantly affect cell properties. In addition, silicon nitride is a material to which tensile stress is applied opposite to silicon oxide included in the base insulation portion 135 or the interlayer insulation layer 132m.

In some embodiments, the base insulation portion 135 may include a silicon nitride, and even in this embodiment, the base insulation portion 135 does not substantially contain hydrogen or contain hydrogen with a lower concentration compared to the hydrogen-containing portion 138. Accordingly, it may be determined that the base insulation portion 135 and the hydrogen-containing portion 138 are formed of different materials.

The barrier portion 139 may be formed of a material that can stably fill a penetration portion 1362a and/or horizontal portion 1362b of the second portion 1362 having a relatively small width or thickness. For example, in an embodiment the barrier portion 139 may include a silicon oxide, a silicon oxynitride, a low dielectric constant material having lower permittivity than silicon oxide, or a combination thereof. As an example, in an embodiment, the barrier portion 139 may include the same material as the insulating material included in the interlayer insulation layer 132m, the upper insulation layers 132a and 132b, and/or the separation structure 146 disposed in the cell array region 102. In some embodiments, the barrier portion 139 may include one or a plurality of layers.

However, embodiments of the present disclosure are not necessarily limited thereto, and the base insulation portion 135, the hydrogen-containing portion 138, or the barrier portion 139 may include a material other than the above-described material.

In an embodiment, the hydrogen-containing insulation portion 136 may have a greater width than the separation structure 146, or may include a portion disposed in a region (e.g., a memory cell block) between the plurality of separation structures 146. Correspondingly, the hydrogen-containing insulation portion 136 may be formed in a relatively wide area regardless of the portion where the separation structure 146 is formed. Thus, hydrogen can be effectively supplied to the memory cell.

In an embodiment, the hydrogen-containing insulation portion 136 may be disposed in a region between the plurality of separation structures 146. For example, in an embodiment, the hydrogen-containing insulation portion 136 may be disposed between two adjacent separation structures 146a and 146b at opposite sides of one memory cell block. As an example, the hydrogen-containing insulation portion 136 may be disposed in a region where the separation structure 146 is not disposed before the separation structure 146 is formed. A stacking structure (reference numeral 120s in FIG. 4A) in which a sacrificial insulation layer (refer to 130s in FIG. 4A) and a cell insulation layer 132 are stacked may then be etched to form an opening for forming the separation structure 146. Accordingly, the opening for forming the separation structure 146 may be formed in the same environment as the forming process of other penetrating portions such that the manufacturing process can be performed more easily. This will be described in more detail later.

As another example, the hydrogen-containing insulation portion 136 may be formed in a region where the separation structure 146 is to be formed before the separation structure 146 is formed. In this embodiment, since a portion of the hydrogen-containing insulation portion 136, which is disposed in the region where the separation structure 146 is to be disposed is removed through the formation process of the separation structure 146, the hydrogen-containing insulation portion 136 is disposed in regions between the separation structures 146 after the separation structure 146 are formed. In addition, even in an embodiment, in which the hydrogen-containing insulation portion 136 is disposed between the separation structures 146, the hydrogen-containing insulation portion 136 may be formed after the separation structure 146 is formed. Numerous other variations are possible.

On a plane, in an embodiment, the hydrogen-containing insulation portion 136 may include a body portion 136a disposed on the second pad portion PP2. In addition, the hydrogen-containing insulation portion 136 may further include an extension portion 136b disposed in the first pad portion PP1. For example, in an embodiment, a bottom surface of the body portion 136a may be disposed on the second pad portion PP2 and thus may have a planar or flat surface. In an embodiment, the bottom surface of the extension portion 136b may have a staircase shape by being disposed on a plurality of first pad portion PP1 having a staircase shape. However, embodiments of the present disclosure are not necessarily limited thereto.

As an example, when viewed from a second direction (e.g., the X-axis direction), the body portion 136a may have a first width W1 (e.g., length in the X-axis direction), and the extension portion 136b may have a second width W2 (e.g., length in the X-axis direction), which is less than the first width W1. Accordingly, it is possible to form the body portion 136a having the relatively large first width W1 in a wide region in which the gate contact portion 184 is not provided in the second pad portion PP2 having a relatively large length. Therefore, the hydrogen-containing insulation portion 136 may be formed to have a sufficient size without adding additional space.

For example, in an embodiment, the body portion 136a may have a shape that extends longitudinally in the first direction (e.g., the Y-axis direction) while having the first width W1 between adjacent separation structures 146a and 146b. The extension portion 136b may have a shape extending in the first direction (e.g., the Y-axis direction) while having the second width W2 between the adjacent separation structures 146a and 146b. In FIG. 1, it is illustrated as an example that the body portion 136a and the extension portion 136b are directly connected to each other. However, embodiments of the present disclosure are not necessarily limited thereto. Thus, in some embodiments the body portion 136a and/or the extension portion 136b may not have the shape extending longitudinally in the first direction. In addition, the body portion 136a and the extension portion 136b may not be directly connected to each other in some embodiments.

In an embodiment, hydrogen-containing insulation portion 136 may include a first portion 1361 disposed on the gate stacking structure 120 (e.g., disposed above the gate stacking structure 120 in the Z-axis direction) and a second portion 1362 including a portion penetrating the gate stacking structure 120 at a lower portion of the first portion 1361. However, embodiments of the present disclosure are not necessarily limited thereto, and the hydrogen-containing insulation portion 136 may include the first portion 1361 without including the second portion 1362 in some embodiments.

For example, in an embodiment, the second portion 1362 may include may include a penetration portion 1362a penetrating the gate stacking structure 120 and extending in a direction crossing (e.g., vertical to) the second substrate 110 (e.g., the Z-axis direction), and a horizontal portion 1362b extending in a horizontal direction from the penetration portion 1362a and disposed between the plurality of gate electrodes 130. For example, in an embodiment, the body portion 136a may include the first portion 1361 and the second portion 1362, and the extension portion 136b may include a first portion 1361 and a second portion 1362.

In this embodiment, the second portion 1362 may be a portion formed by removing a second dummy sacrificial layer (refer to 184f in FIG. 4A), removing the interlayer insulation layer 132m disposed between the sacrificial insulation layers (refer to 130s in FIG. 4A) through a portion where the second dummy sacrificial layer is removed, and then filling an insulating material forming the hydrogen-containing insulation portion 136. This will be described in more detail later.

As described, the penetration portion 1362a of the second portion 1362 is a portion formed in the portion where the second dummy sacrificial layer 184f is removed, and thus it may have the same as or similar to the shape of the dummy structure DH1.

In an embodiment, the hydrogen-containing insulation portion 136 may be disposed in the first portion 1361, and the barrier portion 139 may form the second portion 1362. For example, in an embodiment, the barrier portion 139 may entirely fill the second portion 1362 and may be disposed on lateral side surfaces and a bottom surface of the first portion 1361. In addition, the hydrogen-containing portion 138 may be positioned on the barrier portion 139 in the first portion 1361.

However, embodiments of the present disclosure are not necessarily limited thereto. For example, in some embodiments the barrier portion 139 may be disposed in the second portion 1362, and may not be disposed in the first portion 1361. The hydrogen-containing portion 138 may then directly contact the base insulation portion 135. As another example, the hydrogen-containing insulation portion 136 may not include the barrier portion 139. For example, in an embodiment, the hydrogen-containing portion 138 may be wholly disposed in the first portion 1361 and the second portion 1362, thereby increasing the amount of hydrogen provided to the memory cell. In this embodiment, the hydrogen-containing portion 138 may directly contact the gate electrode 130 and/or the gate contact portion 184.

When viewed on a plane, in the drawing, it is illustrated as an example that the first portion 1361 and the horizontal portion 1362b of the second portion 1362 have the same size or area. For example, lateral side surfaces of the first portion 1361 and lateral side surfaces of the horizontal portion 1362b of the second portion 1362 are positioned on the same plane. However, embodiments of the present disclosure are not necessarily limited thereto. For example, in some embodiments the size or area of the first portion 1361 and the second portion 1362 may be different from each other when viewed on a plane. For example, the size or area of the first portion 1361 may be greater than the size or area of the second portion 1362 on a plane. In this embodiment, the lateral side surfaces of the horizontal portion 1362b of the second portion 1362 may then be disposed more inwardly than the lateral side surfaces of the first portion 1361. In some embodiments, the second portion 1362 may include the penetration portion 1361a without the horizontal portion 1362b.

When there is a difference in size or area between a first penetrating portion (refer to 1361p in FIG. 4C) for forming the first portion 1361 and a second penetrating portion (refer to 1362p in FIG. 4C) for forming the horizontal portion 1362b of the second portion 1362 in the manufacturing process, the above-described structure may be obtained. This will be described in more detail later with respect to the manufacturing method.

As previously stated, a width (e.g., length in the X-axis direction) of the hydrogen-containing insulation portion 136 may be greater than a width W0 of the separation structure 146 when viewed in the second direction (X-axis direction in the drawing). In this embodiment, as previously described, the hydrogen-containing insulation portion 136 is formed in the area including the second dummy sacrificial layer 184f, and therefore the hydrogen-containing insulation portion 136 may have a larger width than of the second dummy sacrificial layer 184f or the dummy structure DH1. For example, when viewed in the second direction, at least a portion of the hydrogen-containing insulation portion 136 may be formed throughout a region where the plurality of gate contact portions 184 are disposed, a region where the plurality of dummy structures DH1 are disposed, or a region where the gate contact portion 184 and the dummy structure DH1 are disposed.

For example, when viewed in the second direction, in one memory cell block disposed between adjacent separation structures 146a and 146b, a plurality of regions where the gate contact portion 184 and/or the dummy structure DH1 is disposed may be disposed in the second direction. For example, in FIG. 1, it is illustrated as an example that a region where the dummy structure DH1 is disposed, a region where the gate contact portion 184 and the dummy structure DH1 are disposed together, a region where the second dummy sacrificial layer 184f or the upper separation region 148 is disposed, a region where the gate contact portion 184 and the dummy structure DH1 are disposed together, and a region where the dummy structure DH1 is disposed are sequentially disposed between the adjacent separation structures 146a and 146b when viewed in the second direction. In this embodiment, in FIG. 1, it is illustrated as an example that the body portion 136a is formed in a portion of the region where the dummy structure DH1 is disposed, in an entire portion of the region where the gate contact portion 184 and the dummy structure DH1 are disposed together, in an entire portion of the region where the second dummy sacrificial layer 184f or the upper separation region 148 is disposed, in an entire portion of the region where the gate contact portion 184 and the dummy structure DH1 are disposed together, and in a portion of the region where the dummy structure DH1 is disposed, between the adjacent separation structures 146a and 146b when viewed in the second direction.

For example, in an embodiment, a width (e.g., length in the X-axis direction) of at least a portion of the hydrogen-containing insulation portion 136 may be at least 50% (e.g., 80% or more) or more of a width (e.g., length in the X-axis direction) between the adjacent separation structures 146a and 146b (e.g., the width of the memory cell block). For example, when viewed in the second direction (e.g., the X-axis direction), a width of the body portion 136a may be 50% or more (e.g., 80% or more) of the width between the adjacent separation structures 146a and 146b. Accordingly, it is possible to sufficiently secure the size of the hydrogen-containing insulation portion 136.

In addition, as mentioned above, in an embodiment, the hydrogen-containing insulation portion 136 may be positioned between the adjacent separation structures 146a and 146b. In this embodiment, the hydrogen-containing insulation portion 136 may be adjacent to the separation structure 146 or spaced apart from the separation structure 146. Accordingly, when viewed in the second direction, the width of the hydrogen-containing insulation portion 136 to the width between the adjacent separation structures 146a and 146b may be 100% or less.

In FIG. 1, it is illustrated as an example that the entire dummy structure DH1 or a portion of the dummy structure DH1 is provided between one separation structure 146 and its adjacent body portion 136a when viewed in the second direction. However, embodiments of the present disclosure are not necessarily limited to the number of dummy structures DH1 disposed between the separation structure 146 and the body portion 136a. For example, the dummy structure DH1 may not be disposed between one separation structure 146 and its adjacent body portion 136a or a plurality of dummy structures DH1 may be disposed therebetween.

In FIG. 1, it is illustrated as an example that two gate contact portions 184 are disposed between adjacent separation structures 146a and 146b and the extension portion 136b includes a central extension portion 136e in the second direction (e.g., the X-axis direction). In the second direction, the central extension portion 136e may be disposed in a central portion between the adjacent separation structures 146a and 146b or in a central portion between two gate contact portions 184 provided therein. The central portion is a portion having a constant width to maintain insulation properties of the two adjacent gate contact portions 184. Therefore, when the central extension portion 136e is positioned at the central portion, an area of the central extension portion 136e may be increased and problems that may occur due to errors in the manufacturing process may be reduced. In addition, the size of the base insulation portion 135 can be sufficiently secured by disposing the base insulation portion 135 in a portion other than the central extension portion 136e.

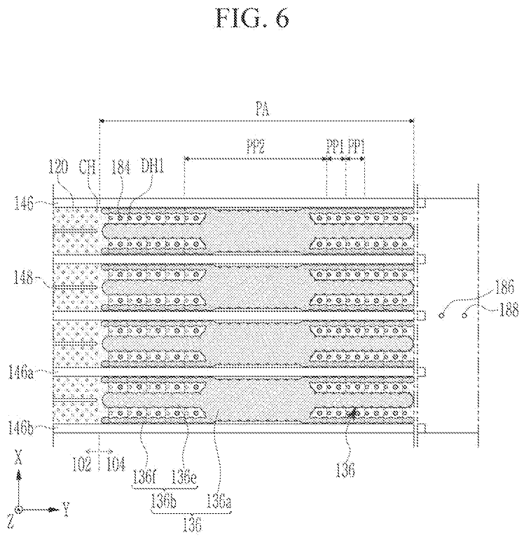

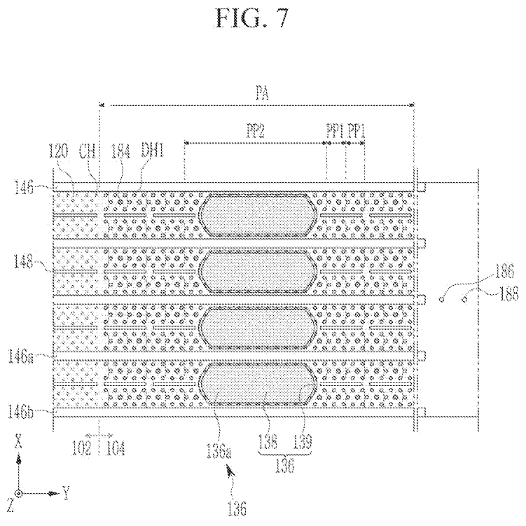

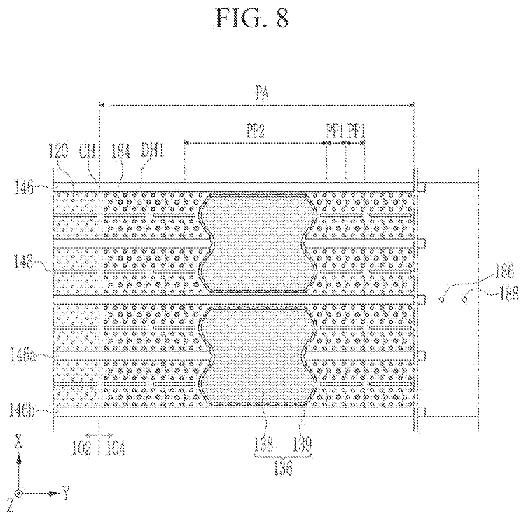

However, embodiments of the present disclosure are not necessarily limited thereto. Thus, three or more gate contact portions 184 may be disposed between the adjacent separation structures 146a and 146b. In this embodiment, the central extension portion 136e may be disposed in a central portion between adjacent separation structures 146a and 146b or between two adjacent gate contact portions 184. In addition, one or a plurality of the central extension portion 136e may be provided. In some embodiments, the extension portion 136b may further include an outer extension portion (refer to 136f of FIG. 6). For example, one or more extension portions 136b may be disposed between the separation structure 146 and the gate contact portion 184 and/or between the gate contact portion 184 and the gate contact portion 184. The outer extension portion 136f will be described in more detail later with reference to FIG. 6. In some embodiments, the extension portion 136b may not be provided, which will be described later in more detail with reference to FIG. 7 or FIG. 8.

In FIG. 1 and the above description, it is illustrated as an example that the first width W1 of the body portion 136a is greater than the second width W2 of the extension portion 136b. However, embodiments of the present disclosure are not necessarily limited thereto. Accordingly, in some embodiments the first width W1 of the body portion 136a may be less than or equal to the second width W2 of the extension portion 136b. Numerous other variations are possible.

According to an embodiment, the insulation layer 134 in the connection region 104 includes the hydrogen-containing insulation portion 136, thereby providing hydrogen to the memory cell. Accordingly, cell properties can be increased by increasing a passivation property of the memory cell. In this embodiment, the hydrogen-containing insulation portion 136 is provided separately from the separation structure 146, and thus, a high degree of freedom in design and a sufficient size may be achieved. In addition, the hydrogen-containing insulation portion 136 is in the connection region 104 and not in the cell array region 102, and thus, the manufacturing process can be performed more easily and stability can be increased. In addition, the insulation layer 134 may increase various properties by including the base insulation portion 135. Accordingly, the performance of the semiconductor device 10 can be effectively increased.

In FIG. 1, it is illustrated as an example that an outer surface of the hydrogen-containing insulation portion 136 or the barrier portion 139 has a rounded shape or convex shape. As an example, the hydrogen-containing insulation portion 136 or the barrier portion 139 has a round shape or a convex shape between the adjacent dummy structures DH1. In an embodiment, the round or convex shape may be a result of the etching of the second dummy sacrificial layer (refer to 184f in FIG. 4A) and the etched portion is then expanded to form a region where the hydrogen-containing insulation portion 136 is to be disposed. However, embodiments of the present disclosure are not necessarily limited thereto, and the outer surface of the hydrogen-containing insulation portion 136 or the barrier portion 139 may be configured as a flat surface or may have a different shape.

In addition, in FIG. 1, it is illustrated as an example that an interface of the barrier portion 139 and the hydrogen-containing portion 138 is formed of a flat surface. However, embodiments of the present disclosure are not necessarily limited thereto, and the barrier portion 139 has a uniform thickness as a whole, and thus the interface between the barrier portion 139 and the hydrogen-containing portion 138 may be the same as or similar to the outer surface of the hydrogen-containing insulation portion 136 or the barrier portion 139. For example, in an embodiment, the interface between the barrier portion 139 and the hydrogen-containing portion 138 may have a rounded shape or a convex shape. However, embodiments of the present disclosure are not necessarily limited thereto and the interface between the barrier portion 139 and the hydrogen-containing portion 138 may have various other shapes.

In FIG. 2, it is illustrated as an example that an upper surface of the hydrogen-containing insulation portion 136 is disposed on the same plane (e.g., in the Z-axis direction) as an upper surface of the channel structure CH and an upper surface of the dummy structure DH1. In addition, in FIG. 2, it is illustrated as an example that the upper surface of the hydrogen-containing insulation portion 136 is positioned lower (e.g., in the Z-axis direction) than an upper surface of the gate contact portion 184 and an upper surface of the separation structure 146. This is according to an example of the manufacturing process, but embodiments of the present disclosure are not necessarily limited thereto.

According to the manufacturing process, the upper surfaces of the hydrogen-containing insulation portion 136, the channel structure CH, the dummy structure DH1, the gate contact portion 184, and the separation structure 146 may be disposed in any of various positions. For example, in an embodiment, the upper surface of the hydrogen-containing insulation portion 136 is disposed on a different plane (e.g., in the Z-axis direction) from the upper surface of the channel structure CH and/or dummy structure DH1, or disposed on the same plane (e.g., in the Z-axis direction) as the gate contact portion 184 and/or the separation structure 146. In addition, the upper surface of the channel structure CH and the upper surface of the dummy structure DH1 may be positioned on different planes from each other. The upper surface of the gate contact portion 184 and/or the separation structure 146 may be disposed at the same position as or lower than the upper surface of the channel structure CH and/or the dummy structure DH1. In addition, the upper surfaces of the gate contact portion 184 and the separation structure 146 may be disposed on different planes from each other (e.g., in the Z-axis direction). Numerous other variations are possible.

In the above-described embodiment, the hydrogen-containing insulation portion 136 is disposed together in the plurality of gate stacking structures 120a and 120b. However, embodiments of the present disclosure are not necessarily limited thereto. For example, the hydrogen-containing insulation portion 136 may be disposed in some of the plurality of gate stacking structures 120a and 120b. Numerous other variations are possible.

An example of a manufacturing method for manufacturing the semiconductor device 10 having the above structure will be described in detail with reference to FIG. 1 to FIG. 3 and FIG. 4A to FIG. 4H. For the parts that have already been explained, the detailed description may be omitted for economy of description, and the parts not explained in detail are mainly explained.

FIG. 4A to FIG. 4H are partial cross-sectional views of a manufacturing method of a semiconductor device according to embodiments of the present disclosure. In FIG. 4A to FIG. 4F and FIG. 4H, partial cross-sectional views of the semiconductor device 10, taken along the lines A1-A2, B1-B2, and B3-B4 are illustrated, and FIG. 4G shows an enlarged view of portions of a wiring penetration portion OH and a tunnel portion TL. Hereinafter, the manufacturing method of the semiconductor device 10 will mainly be described with respect to the gate stacking structure 120, the channel structure CH, the gate contact portion 184, the insulation layer 134, and the separation structure 146 disposed in the connection region 104.

As shown in FIG. 4A, the stacking structure 120s may be formed by alternately stacking (e.g., in the Z-axis direction) a plurality of sacrificial insulation layers 130s and a plurality of cell insulation layers 132 in the circuit region 200 including the peripheral circuit structure. The second substrate 110, the horizontal insulation layer 116, the second horizontal conductive layer 114, or the like may be further formed between the circuit region 200 and the stacking structure 120s (e.g., in the Z-axis direction). In addition, a channel sacrificial layer 124d, a wiring sacrificial layer 184d, and dummy sacrificial layers 184e and 184f that penetrate the stacking structure 120s may be formed.

For brief description and clear understanding, in the drawing and description, it is illustrated that the stacking structure 120s includes a plurality of stacking structures 120d and 120e including a first stacking structure 120d and a second stacking structure 120e. However, embodiments of the present disclosure are not necessarily limited thereto, and the stacking structure 120s may include one or three or more stacking structures in some embodiments.

In an embodiment, the horizontal insulation layer 116 and the second horizontal conductive layer 114 may first be formed on the second substrate 110, and then the first stacking structure 120d may be formed on the second substrate 110. For example, the cell insulation layer 132 and the sacrificial insulation layer 130s may be alternately stacked (e.g., in the Z-axis direction). In this embodiment, the first upper insulation layer 132a may be at an upper portion of the first stacking structure 120d. In addition, the channel sacrificial layer 124d, the wiring sacrificial layer 184d, and the dummy sacrificial layers 184e and 184f penetrating the first stacking structure 120d may be formed.

In an embodiment, the sacrificial insulation layer 130s may be a layer replaced with a gate electrode (refer to 130 in FIG. 4H) through a subsequent process, and at least a portion of the horizontal insulation layer 116 may be a layer replaced with a first horizontal conductive layer (refer to 112 in FIG. 4H) through a subsequent process. For example, the sacrificial insulation layer 130s may be formed to correspond to a portion where the gate electrode 130 is to be formed, and the horizontal insulation layer 116 may be formed to include a portion where the first horizontal conductive layer 112 is to be formed.

In an embodiment, the horizontal insulation layer 116 and/or the sacrificial insulation layer 130s may be formed of a material different from that of the interlayer insulation layer 132m and/or the first upper insulation layer 132a. For example, in an embodiment, the interlayer insulation layer 132m or the first upper insulation layer 132a may include a silicon oxide, a silicon nitride, a silicon oxynitride, a low dielectric constant material, or the like, and the sacrificial insulation layer 130s includes one of silicon, a silicon oxide, a silicon carbide, a silicon nitride, or the like, and may be formed of a material different from that of the interlayer insulation layer 132m.

Subsequently, in the first stacking structure body 120d, a recess portion RP may be formed to correspond to the pad region (refer to PA in FIG. 1) to which the gate electrode 130 and a gate contact portion (refer to 184 in FIG. 4H) are connected. Such a recess portion RP may be formed by a sequential etching process using a mask layer. For example, in an embodiment, the recess portion RP may be formed by performing a stepwise etching process on the sacrificial insulation layer 130s and the cell insulation layer 132 while sequentially increasing the exposed regions using a mask layer.

Subsequently, a thickness (e.g., length in the Z-axis direction) of the sacrificial insulation layer 130s in the pad portions PP1 and PP2 of the gate electrode 130 may be increased from a thickness (e.g., length in the Z-axis direction) of the sacrificial insulation layer 130s in other portions. For example, in an embodiment, after forming the additional sacrificial insulation layer, the thickness of the sacrificial insulation layer 130s of the pad portions PP1 and PP2 may be increased by patterning such that the additional sacrificial insulation layer remains on the pad portions PP1 and PP2.

Subsequently, the first upper insulation layer 132a may be formed to entirely cover the sacrificial insulation layer 130s and the interlayer insulation layer 132m. In an embodiment, a pad insulation portion of the connection region 104 filling the recess portion RP in the first stacking structure 120d may be formed before or after the process of forming the first upper insulation layer 132a separately from the first upper insulation layer 132a, and may be formed of a portion of the first upper insulation layer 132a.

In an embodiment, the channel sacrificial layer 124d penetrating the first stacking structure 120d may then be formed in the cell array region 102, and the wiring sacrificial layer 184d and the dummy sacrificial layers 184e and 184f penetrating the first stacking structure 120d may be formed in the connection region 104. The channel sacrificial layer 124d, the wiring sacrificial layer 184d, and the dummy sacrificial layers 184e and 184f will be described in detail later.

In an embodiment, the channel sacrificial layer 124d, the wiring sacrificial layer 184d, and the dummy sacrificial layers 184e and 184f provided in the first stacking structure 120d may be formed by depositing a sacrificial material after forming a penetrating portion penetrating the first stacking structure 120d. For example, in an embodiment, the penetrating portion may be formed by an etching process (e.g., a plasma etching process), and the sacrificial material may include polysilicon, tungsten, or the like.

In an embodiment, the second stacking structure 120e may then be formed. For example, the cell insulation layer 132 and the sacrificial insulation layer 130s may be alternately stacked (e.g., in the Z-axis direction). In an embodiment, the second upper insulation layer 132b may be at an upper portion of the second stacking structure 120e. In addition, the channel sacrificial layer 124d, the wiring sacrificial layer 184d, and the dummy sacrificial layers 184e and 184f penetrating the second stacking structure 120e may be formed.

For the manufacturing process of the sacrificial insulation layer 130s, the cell insulation layer 132, the recess portion RP, the pad portions PP1 and PP2, the second upper insulation layer 132b, the channel sacrificial layer 124d, the wiring sacrificial layer 184d, and the dummy sacrificial layers 184e and 184f of the second stacking structure 120e, the description related to the first stacking structure 120d may be applied as it is, and therefore the detailed description is omitted for economy of description.

In an embodiment, the channel sacrificial layer 124d may be formed to correspond to the channel structure (refer to CH in FIG. 4H). The wiring sacrificial layer 184d may be formed to correspond to the gate contact portion 184 formed on the gate stacking structure (refer to 120 in FIG. 4H). The dummy sacrificial layers 184e and 184f may include a first dummy sacrificial layer 184e formed to correspond to a dummy structure (refer to DH1 in FIG. 4H) formed in the gate stacking structure 120, and a second dummy sacrificial layer 184f for forming a hydrogen-containing insulation portion (refer to 136 in FIG. 4H).

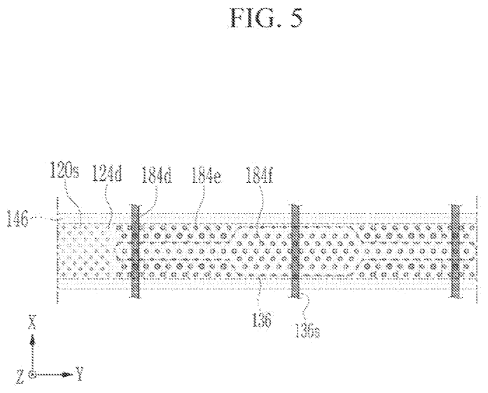

For example, the dummy sacrificial layers 184e and 184f may be disposed to form a polygon shape (e.g., hexagonal shape) as shown in FIG. 5. However, embodiments of the present disclosure are not necessarily limited thereto, and the arrangement of the dummy sacrificial layers 184e and 184f may be variously modified.

In an embodiment, an insulation layer disposed at a portion where the gate contact portion 184 is positioned in the connection region 104 may be referred to as a base insulation layer 135a. In an embodiment, the base insulation layer 135a may include an interlayer insulation layer 132m, upper insulation layers 132a and 132b, a pad insulation layer formed on the pad area PA, or the like. For example, in an embodiment, the base insulation layer 135a may include a silicon oxide, a silicon nitride, a silicon oxynitride, a low dielectric constant material having lower permittivity than silicon oxide, or a combination thereof. However, embodiments of the present disclosure are not necessarily limited thereto.

Subsequently, as shown in FIG. 4B, a portion of the dummy sacrificial layer (refer to 184e and 184f in FIG. 4A) may be removed to form the penetrating portion 136p. For example, in an embodiment, the penetrating portion 136p may be formed at a portion where the second dummy sacrificial layer 184f is disposed by selectively removing the second dummy sacrificial layer 184f without removing the first dummy sacrificial layer 184e. For example, a mask selectively exposing the second dummy sacrificial layer 184f may be formed using a photolithography process, and the second dummy sacrificial layer 184f may be removed by any of various etching processes such as dry etching and wet etching. However, embodiments of the present disclosure are not necessarily limited thereto and various processes may be applied.

Subsequently, as shown in FIG. 4C, a first penetrating portion 1361p and/or a second penetrating portion 1362p may be formed by performing an etching process in the horizontal direction from the penetrating portion (refer to 136p in FIG. 4B). For example, in an embodiment, an etching material is injected through the penetrating portion 136p such that the base insulation layer (refer to 135a in FIG. 4B) is etched in the horizontal direction in a portion adjacent to the penetrating portion 136p such that first penetrating portion 1361p and the second penetrating portion 1362p can be formed. In an embodiment, as the etching process, a wet etching process using an etching material that can selectively etch a material (e.g., silicon oxide, etc.) forming the base insulation layer 135a may be used. However, embodiments of the present disclosure are not necessarily limited thereto.

In further detail, a portion of the base insulation layer 135a (e.g., the second upper insulation layer 132b, the pad insulation portion, or the like) at an upper portion of the stacking structure 120s is etched in the portion adjacent to the penetrating portion 136p, thereby forming the first penetrating portion 1361p. In addition, the base insulation layer 135a (e.g., an interlayer insulation layer 132m) disposed within the stacking structure 120s at a portion adjacent to the penetrating portion 136p may be etched to form a second penetrating portion 1362p. The first penetrating portion 1361p may be a penetrating portion formed to correspond to a portion where a first portion (refer to 1361 in FIG. 4E) is to be formed. The second penetrating portion 1362p may be a penetrating portion formed to correspond to a portion where a second portion (refer to 1362 in FIG. 4E) is to be formed.

In FIG. 4C, when viewed on a plane, it is illustrated as an example that the size or the area of the first penetrating portion 1361p formed by etching the base insulation layer 135a (hereinafter, upper base insulation layer) at the upper portion of the stacking structure 120s and the size or the area of the second penetrating portion 1362p formed by etching the interlayer insulation layer 132m are the same. However, embodiments of the present disclosure are not necessarily limited thereto. There is a difference in the degree of etching of the upper base insulation layer and the interlayer insulation layer 132m due to differences, for example, in shape, material, or the like, and thus the first penetrating portion 1361p and the second penetrating portion 1362p may be different from each other in size or area. As another example, the size or area of the first penetrating portion 1361p and the second penetrating portion 1362p may be different from each other according to the design. For example, in an embodiment, the area of the second penetrating portion 1362p may be less than the area of the first penetrating portion 1361p. In some embodiments, the interlayer insulation layer 132m may not be etched when the first penetrating portion 1361p is formed. In this embodiment, the second penetrating portion 1362p may be formed of the penetrating portion 136p.

As described, a portion of the base insulation layer 135a is etched to be used to form a hydrogen-containing insulation portion (refer to 136 in FIG. 4E), and another portion of the base insulation layer 135a remains to form a base insulation portion (refer to 135 in FIG. 4E).

In some embodiments, an upper support member 136s that supports the stacking structure 120s may be further formed before the forming process of the penetrating portion 136p and/or the first and second penetrating portions 1361p and 1362p, and this will be described in detail with reference to FIG. 5. FIG. 5 is provided for description of the upper support member 136s, which may be used in the manufacturing method of the semiconductor device according to an embodiment.

For clear understanding, in FIG. 5, a region where the separation structure 146 and hydrogen-containing insulation portion 136 will be formed is marked with a dotted line boundary. In addition, in FIG. 5, the position of the upper support member 136s on the stacking structure 120s before the penetrating portion 136p is formed is shown. However, the upper support member 136s may be formed before the formation of the penetrating portion 136p or after the formation of the penetrating portion 136p. In an embodiment, in which the upper support member 136s is formed before the penetrating portion 136p is formed, the upper support member 136s may be formed in a portion where the second dummy sacrificial layer 184f is not disposed.

In FIG. 5, it is illustrated as an example that the upper support member 136s has a shape extending in the second direction (e.g., the X-axis direction), and disposed at regular intervals in the first direction (e.g., the Y-axis direction). Accordingly, the area of the upper support member 136s may be reduced and the upper support member 136s may stably support the stacking structure 120s after forming the first and second penetrating portions 1361p and 1362p to prevent the stacking structure 120s from tilting or collapsing. However, embodiments of the present disclosure are not necessarily limited thereto, and the shape, position, arrangement, number, or the like of the upper support member 136s may be variously modified.

The upper support member 136s may be removed after the barrier portion 139 is formed or after the hydrogen-containing portion 138 is formed. For example, the upper support member 136s may be formed of an insulating material that can be easily formed and removed and does not affect cell properties. However, embodiments of the present disclosure are not necessarily limited thereto, and the upper support member 136s may be formed of any of various materials. In addition, in some embodiments the upper support member 136s may not be formed.

Subsequently, as shown in FIG. 4D and FIG. 4E, the first penetrating portion (refer to 1361p in FIG. 4C) and the second penetrating portion (refer to 1362p in FIG. 4C) are filled with an insulating material such that the hydrogen-containing insulation portion 136 including a first portion 1361 and a second portion 1362 may be formed.

For example, as shown in FIG. 4D, the barrier portion 139 may be formed to fill the second portion 1362. In this embodiment, the barrier portion 139 may also be formed on a bottom surface and lateral side surfaces of the first portion 1361. The barrier portion 139 may be formed by any of various deposition processes that can stably fill the second portion 1362 provided with the penetrating portion 1362a and/or the horizontal portion 1362b. For example, in an embodiment, the barrier portion 139 may be formed through an atomic layer deposition process or the like. However, embodiments of the present disclosure are not necessarily limited thereto.

In an embodiment, as shown in FIG. 4E, in the first portion 1361, the hydrogen-containing portion 138 may then be formed by filling an insulating material containing hydrogen on the barrier portion 139. For example, in an embodiment, the hydrogen-containing portion 138 may be formed through a chemical vapor deposition process (CVD) or an atomic layer deposition process. However, embodiments of the present disclosure are not necessarily limited thereto.

For example, in an embodiment, in which the hydrogen-containing portion 138 is formed by a chemical vapor deposition process, it may contain a greater amount of hydrogen than by an atomic layer deposition process. In an embodiment, in which the hydrogen-containing portion 138 is formed by an atomic layer deposition process, the barrier portion 139 and the hydrogen-containing portion 138 may be formed by an in-situ process continuously performed in the same equipment. Accordingly, the manufacturing process can be simplified. However, embodiments of the present disclosure are not necessarily limited thereto.

In an embodiment, when forming the hydrogen-containing portion 138, a hydrogen supply material that can supply hydrogen may be included, and various materials including hydrogen may be used as the hydrogen supply material. For example, in an embodiment, methane, silane (SiH₄), or the like may be used as a hydrogen supply material. However, embodiments of the present disclosure are not necessarily limited thereto.

In an embodiment, as shown in FIG. 4F to FIG. 4H, the channel sacrificial layer (refer to 124d in FIG. 4E), the wiring sacrificial layer (refer to 184d in FIG. 4E), the first dummy sacrificial layer (refer to 184e in FIG. 4E) are removed, and the channel structure CH, the gate contact portion 184, the gate electrode 130, and the dummy structure DH1 may then be formed.

For example, as shown in FIG. 4F, the channel structure CH may be formed, the dummy structure DH1 may be formed, and the wiring penetrating portion OH may be formed. The upper separation region 148 may be further formed on a portion of the second stacking structure 120e. In an embodiment, the upper separation region 148 may be formed by forming an opening for the upper separation by an etching process using a mask layer and depositing an insulating material in the opening for upper separation.

In an embodiment, the channel structure CH may be formed in the penetrating portion formed by removing the channel sacrificial layer 124d. For example, in an embodiment, a gate dielectric layer (refer to 150 in FIG. 3), a channel layer (refer to 140 in FIG. 3), and a core insulation layer (refer to 142 in FIG. 3) are sequentially formed to fill the penetrating portion, and a channel pad (refer to 144 in FIG. 3) is formed on the channel layer 140 to form the channel structure CH. In this embodiment, a first blocking layer (refer to 156a of FIG. 3,) among the gate dielectric layer 150 may not be formed and may be formed later in another process.

In an embodiment, a dummy structure DH1 may be formed in the penetrating portion formed by removing the first dummy sacrificial layer 184e. For example, a material forming the dummy structure DH1 may be formed to fill the penetrating portion. In an embodiment, the dummy structure DH1 may be formed together with the channel structure CH in the same process and formed of the same structure, shape, material, or the like, or formed in a process separate from the channel structure CH to have a different structure, shape, material, or the like.

In addition, the wiring penetrating portion OH may be formed by removing the wiring sacrificial layer 184d. A portion of the cell insulation layer 132 covering the channel structure CH may be further formed before forming the wiring penetrating portion OH. For example, in an embodiment, a portion of the above-described cell insulation layer 132 may include a silicon oxide, a silicon nitride, a silicon oxynitride, or a low dielectric constant material having lower permittivity than silicon oxide, or a combination thereof. However, embodiments of the present disclosure are not necessarily limited thereto.

The wiring penetrating portion OH may penetrate the stacking structure 120s and a second insulation portion 110i of the second substrate 110 (e.g., in the Z-axis direction) and thus may extend to the circuit region 200. The wiring penetrating portion OH may be formed to expose the pad portion of the circuit region 200.

In an embodiment, as shown in FIG. 4G, the tunnel portion TL may be formed, and a preliminary insulation layers 184j and a vertical sacrificial layer 183c may be formed.

For example, in an embodiment, a portion of the sacrificial insulation layer 130s exposed through the wiring penetrating portion OH is removed in the horizontal direction such that the tunnel portion TL can be formed. When the etching material is inflowed through the wiring penetrating portion OH, the sacrificial insulation layer 130s adjacent to the wiring penetrating portion OH is etched in the horizontal direction, thereby forming the tunnel portion TL. For example, etching may also be performed in upper and lower directions of the sacrificial insulation layer 130s to form the tunnel portion TL with a slightly greater thickness than the sacrificial insulation layer 130s. However, embodiments of the present disclosure are not necessarily limited thereto. As such, since the tunnel portion TL is formed by etching in the horizontal direction through the wiring penetrating portion OH, a side surface of the tunnel portion TL may have a relatively small inclination or may include a convex shape or a rounded portion.

The tunnel portion TL may be formed to have a relatively short length in pad portions (refer to PP1 and PP2 in FIG. 4E) of the connection gate electrode 130c and may have a relatively long length in other gate electrodes 130r.

In an embodiment, the preliminary insulation layer 184j and the vertical sacrificial layer 183c may then be filled in the tunnel portion TL and wiring penetrating portion OH.

In an embodiment, a portion of the preliminary insulation layer 184j may remain and may be a layer forming an insulation pattern (refer to 184i in FIG. 4H). The preliminary insulation layer 184j does not completely fill the tunnel portion TL formed in correspondence with the pad portion PP1 and PP2 of the connection gate electrode (refer to 130c of FIG. 2, the same hereinafter) having a relatively large thickness, but may fill the tunnel portion TL formed corresponding to the remaining gate electrode (refer to 130r in FIG. 4H). This may be due to the relative thickness difference. The vertical sacrificial layer 183c may be formed to fill the remaining space in the wiring penetrating portion OH.

In an embodiment, the preliminary insulation layer 184j may be formed of a material forming the insulation pattern 184i. The vertical sacrificial layer 183c may include a material different from that of the preliminary insulation layer 184j, and may include for example, polysilicon, tungsten, or the like. However, embodiments of the present disclosure are not necessarily limited thereto, and the material of the preliminary insulation layer 184j and/or the vertical sacrificial layer 183c may be variously modified.

In an embodiment, as shown in FIG. 4H, the sacrificial insulation layer (refer to 130s in FIG. 4F and FIG. 4G) may then be replaced with the gate electrode 130 to form a gate contact portion 184.

In an embodiment, an opening may first be formed in a region corresponding to the separation structure (refer to 146 in FIG. 2) to pass through (e.g., in the Z-axis direction) the stacking structure (refer to 120s in FIG. 4F). In an embodiment, the sacrificial insulation layer 130s may be selectively removed by an etching process (e.g., wet etching process) through the opening. In addition, the gate electrode 130 may be formed by burying a conductive material forming the gate electrode 130 in a portion from which the sacrificial insulation layer 130s is removed. Accordingly, the gate stacking structure 120 may be formed by replacing the region where the sacrificial insulation layer 130s is positioned with the gate electrode 130. In this embodiment, a process of forming the first blocking layer 156a may be further performed before the process of burying the conductive material forming the gate electrode 130.

In an embodiment, in which the hydrogen-containing insulation portion 136 is not formed in a portion where the separation structure 146 is to be formed, as shown in FIG. 2, the sacrificial insulation layer 130s, the interlayer insulation layer 132m, and the upper insulation layers 132a and 132b in the connection region 104 are etched to form an opening for forming the separation structure 146. Accordingly, the opening for forming the separation structure 146 may be formed in the same environment as the penetrating portion for forming the channel sacrificial layer 124d, the wiring sacrificial layer 184d, and/or the dummy sacrificial layers 184e and 184f. Accordingly, the same or similar process conditions may be applied such that the manufacturing process can be more easily carried out.

As another example, in an embodiment, in which the hydrogen-containing insulation portion 136 is formed to pass through the region where separation structure 146 is to be formed, as shown in FIG. 8, the sacrificial insulation layer 130s, the interlayer insulation layer 132m, the upper insulation layers 132a and 132b, and the hydrogen-containing insulation portion 136 in the connection region 104 are etched to form the opening for forming the separation structure 146. Even in this embodiment, the opening for forming the separation structure 146 is filled with an insulating material (e.g., silicon oxide) that forms the separation structure 146. Therefore, in the final structure, the hydrogen-containing insulation portion 136 is disposed in a region between the separation structures 146 when viewed in the second direction (X-axis direction of the drawing). In this embodiment, the hydrogen-containing insulation portion 136 may include a portion positioned in direct contact with the separation structure 146.

In some embodiments, the opening for forming the separation structure 146 may be formed to expose the horizontal insulation layer 116. In the etching process through the opening for forming the separation structure 146, at least a portion of the horizontal insulation layer 116 and a portion of the gate dielectric layer 150 are removed, and the material forming the first horizontal conductive layer 112 is filled to form the first horizontal conductive layer 112.

In addition, in an embodiment, an insulating material may be filled in the opening for forming the separation structure 146 to form the separation structure 146.

In an embodiment, the vertical sacrificial layer (refer to 183c in FIG. 4G) and a portion of the preliminary insulation layer (refer to 184j in FIG. 4G, the same hereinafter) are removed, and the gate contact portion 184 may be formed by filling with a conductive material.

For example, in an embodiment, a portion of the preliminary insulation layer 184j may be removed after selectively removing the vertical sacrificial layer 183c. In this embodiment, an entire portion of the preliminary insulation layers 184j formed in the pad portions PP1 and PP2 of the connection gate electrode 130c may be removed, and the preliminary insulation layer 184j formed on the tunnel portion TL of the remaining gate electrode 130r may remain to form the insulation pattern 184i.

In an embodiment, the gate contact portion 184 may then be formed by depositing a conductive material in the wiring penetrating portion OH. The gate contact portion 184 has a connection portion 184c protruded to inner surfaces of the pad portions PP1 and PP2. In an embodiment, a second wiring portion 180 connected to the channel structure CH may then be formed.

According to an embodiment, the hydrogen-containing insulation portion 136 is in a portion where a portion of the base insulation layer 135a in the connection region 104 is removed, and the insulation layer 134 including the base insulation portion 135 and the hydrogen-containing insulation portion 136 is in a portion where the gate contact portion 184 is disposed in the connection region 104. Accordingly, the semiconductor device 10 having excellent performance can be formed through an easy process, and productivity can be increased.

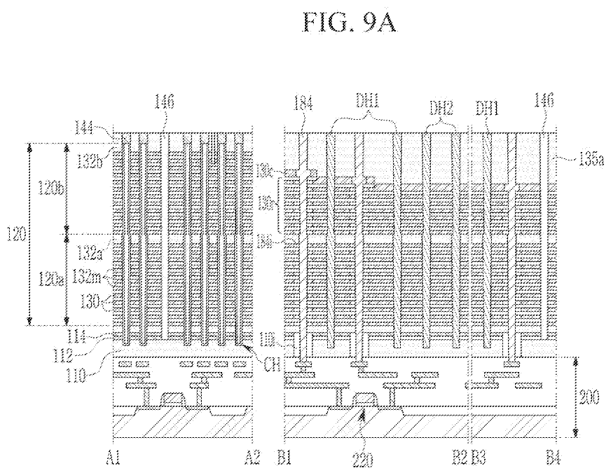

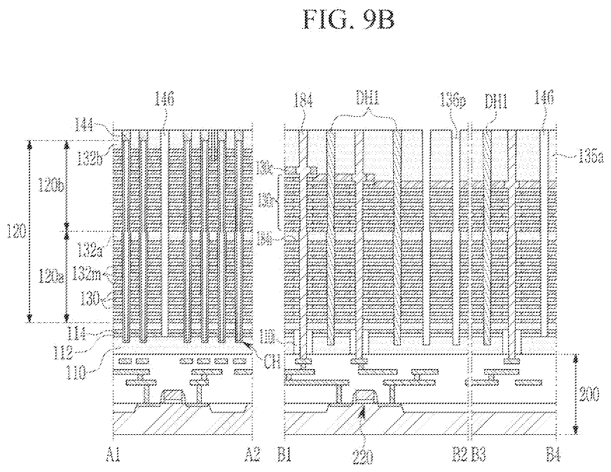

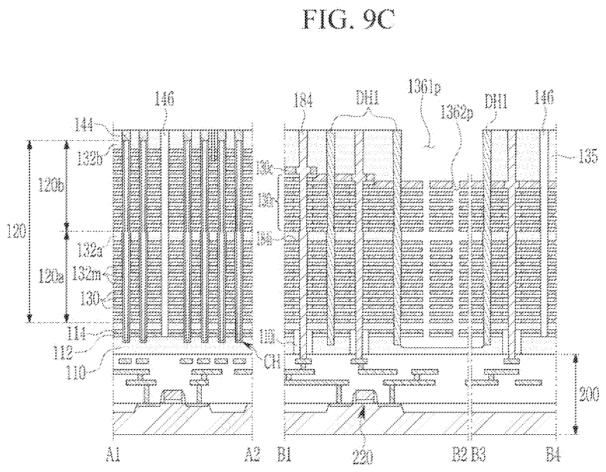

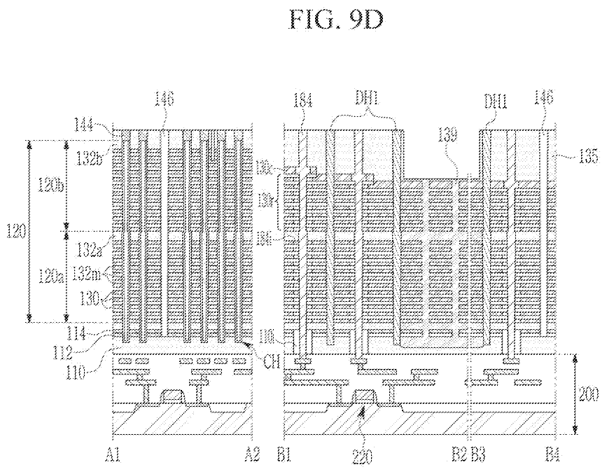

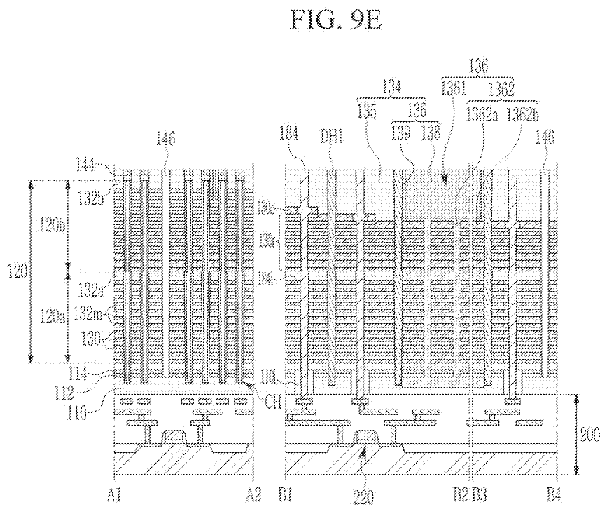

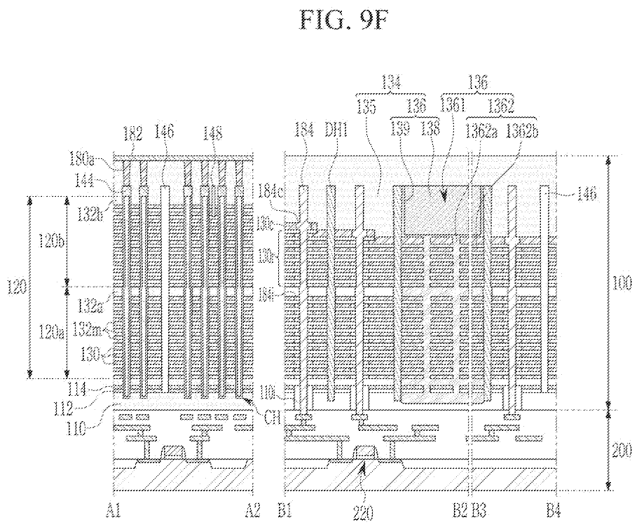

Hereinafter, a semiconductor device according to an embodiment that is different from the above-described embodiment will be described in more detail with reference to FIG. 6 to FIG. 8, and FIG. 9A to FIG. 9F. For portions identical or extremely similar to those already described, detailed descriptions are omitted, and only other portions are described in detail.

FIG. 6 is a partial top plan view of a semiconductor device according to an embodiment.

Referring to FIG. 6, a hydrogen-containing insulation portion 136 may include a plurality of extension portions 136b between adjacent separation structures 146a and 146b in a second direction (e.g., the X-axis direction). In FIG. 6, it is illustrated as an example that two gate contact portions 184 are disposed between adjacent separation structures 146a and 146b, and an extension portion 136b includes a central extension portion 136e and two outer extension portions 136f respectively disposed between one separation structure 146a and the gate contact portion 184 adjacent to the one separation structure 146a and between the other separation structure 146b and the gate contact portion 184 adjacent to the other separation structure 146b. Accordingly, the area of the extension portion 136b can be increased.

However, embodiments of the present disclosure are not necessarily limited thereto. For example, in some embodiments one or three or more gate contact portions 184 may be positioned between the adjacent separation structures 146a and 146b, and one or a plurality of outer extension portions 136f may be provided. In addition, in some embodiments the central extension portion 136e may not be provided.

In this embodiment, a hydrogen-containing insulation portion 136 may include a hydrogen-containing portion and a barrier portion, and the hydrogen-containing insulation portion 136 may include a hydrogen-containing portion. Numerous other variations are possible.

In addition, in FIG. 6, it is illustrated as an example that the central extension portion 136e and/or the outer extension portion 136f are extended in the first direction (e.g., the Y-axis direction), and a body portion 136a and the plurality of extension portion 136b are directly connected to each other. However, embodiments of the present disclosure are not necessarily limited thereto. Accordingly, the body portion 136a and/or the extension portion 136b may not have a shape extending in the first direction. In addition, the body portion 136a and the extension portion 136b may not be directly connected to each other.

FIG. 7 is a partial top plan view of a semiconductor device according to an embodiment.

Referring to FIG. 7, a hydrogen-containing insulation portion 136 may include a body portion 136a between adjacent separation structures 146a and 146b in a second direction (e.g., in the X-axis direction) in a second pad portion PP2 and may not include an extension portion (refer to 136b in FIG. 1 and FIG. 6) in a first pad portion PP1.

Correspondingly, the hydrogen-containing insulation portion 136 may be periodically disposed with the plurality of first pad portion PP1 interposed in the first direction (e.g., the Y-axis direction of the drawing). However, embodiments of the present disclosure are not necessarily limited thereto.

FIG. 8 is a partial top plan view of a semiconductor device according to an embodiment.

Referring to FIG. 8, in an embodiment, a hydrogen-containing insulation portion 136 may be disposed over, or across, a plurality of memory cell blocks by passing through at least one separation structure 146 in a second direction (e.g., the X-axis direction). Accordingly, a sufficient size of the hydrogen-containing insulation portion 136 may be maintained.

For example, in an embodiment, the hydrogen-containing insulation portion 136 may be formed after the separation structure 146 is formed. Since first and second penetrating portions for forming the hydrogen-containing insulation portion 136 are formed in a state that the separation structure 146 is formed, the hydrogen-containing insulation portion 136 may be formed regardless of the separation structure 146.

In FIG. 8, it is illustrated as an example that the hydrogen-containing insulation portion 136 includes a barrier portion 139 and a hydrogen-containing portion 138. However, embodiments of the present disclosure are not necessarily limited thereto. For example, in some embodiments the barrier portion 139 may not be provided. In addition, in FIG. 8, it is illustrated as an example that the hydrogen-containing insulation portion 136 includes a body portion 136a and does not include an extension portion (refer to 136b in FIG. 1 and FIG. 6). However, embodiments of the present disclosure are not necessarily limited thereto. For example, in some embodiments one or a plurality of extension portions 136b may be further provided. For example, an embodiment referring to FIG. 1 and an embodiment referring to FIG. 6 may be equally applied to an embodiment described with reference to FIG. 8.

An example of a manufacturing method of the semiconductor device shown in FIG. 8 will be described in detail with reference to FIG. 9A to FIG. 9F. FIG. 9A to FIG. 9F are partial cross-sectional views of a manufacturing method of the semiconductor device shown in FIG. 8.

FIG. 9A to FIG. 9F illustrate partial cross-sectional views corresponding to the lines A1-A2, B1-B2, and B3-B4 of FIG. 1. Hereinafter, a manufacturing method of the semiconductor device 10 will be mainly focused on the gate stacking structure 120, the channel structure CH, the gate contact portion 184, and the insulation layer 134 disposed in the connection region, and the separation structure 146.

As shown in FIG. 9A, the plurality of sacrificial insulation layers 130s and the plurality of cell insulation layers 132 may be alternately stacked on the circuit region 200 (e.g., in the Z-axis direction) to form the stacking structure 120s. The second substrate 110, the horizontal insulation layer 116, and the second horizontal conductive layer 114 may further be formed between the circuit region 200 and the stacking structure 120s. In addition, the channel sacrificial layer, the wiring sacrificial layer, and the first and second dummy sacrificial layer that penetrate the stacking structure 120s may be formed. Regarding this, the description referring to FIG. 4A may be applied as it is, and therefore the detailed description is omitted for economy of description.

In an embodiment, the channel sacrificial layer, the wiring sacrificial layer, and the first and second dummy sacrificial layer are then removed, and the channel structure CH, the gate contact portion 184, the gate electrode 130, the dummy structure DH1, and a preliminary dummy structure DH2 may be formed.

For example, in an embodiment, the channel structure CH may be formed, the dummy structure DH1 and the preliminary dummy structure DH2 may be formed, and wiring penetrating portion OH may be formed. In addition, a tunnel portion TL may be formed, and a preliminary insulation layer 184j and a vertical sacrificial layer 183c may be formed. In addition, an opening for forming a separation structure 146 is formed such that the sacrificial insulation layer (refer to 130s in FIG. 4F and FIG. 4G) can be replaced with the gate electrode 130 and the gate contact portion 184 can be formed. In an embodiment, the separation structure 146 may be formed by filling the opening for forming the separation structure 146 with an insulating material or the like.

In this embodiment, the base insulation layer 135a may be in a state in which the penetrating portion (refer to 1361p and 1362p in FIG. 9C) is not provided. Except for forming the preliminary dummy structure DH2 together with the dummy structure CH in the process of forming the dummy structure DH1, the description referring to FIG. 4F to FIG. 4H may be applied as it is.

In an embodiment, as shown in FIG. 9B, the preliminary dummy structure (refer to DH2 in FIG. 9A) may be removed to form the penetrating portion 136p. For example, the preliminary dummy structure DH2 may be selectively removed without removing the dummy structure DH1 to form the penetrating portion 136p at a position where the preliminary dummy structure DH2 was positioned. For example, in an embodiment, a mask that selectively exposes the preliminary dummy structure DH2 may be formed using a photolithography process, and the preliminary dummy structure DH2 may be removed by any of various etching processes such as dry etching and wet etching. However, embodiments of the present disclosure are not necessarily limited thereto and various processes may be applied.

In an embodiment, as shown in FIG. 9C, the first penetrating portion 1361p and the second penetrating portion 1362p may be formed by performing an etching process in a penetrating portion (refer to 136p in FIG. 9B). For example, in an embodiment, an etching material is injected through the penetrating portion 136p such that the base insulation layer (refer to 135a in FIG. 9B) is etched in the horizontal direction in a portion adjacent to the penetrating portion 136p such that first penetrating portion 1361p and the second penetrating portion 1362p can be formed. In an embodiment, the etching process may be a wet etching process using an etching material that can selectively etch a material (e.g., silicon oxide, etc.) forming the base insulation layer 135a. However, embodiments of the present disclosure are not necessarily limited thereto.

As described, a portion of the base insulation layer 135a is etched and used to form a hydrogen-containing insulation portion (refer to 136 in FIG. 9E), and the other portion of the base insulation layer 135a may remain to form the base insulation portion 135.

In an embodiment, as shown in FIG. 9D and FIG. 9E, the hydrogen-containing insulation portion 136 including the first portion 1361 and the second portion 1362 may then be formed by filling an insulating portion that forms the hydrogen-containing insulation portion 136 in the first penetrating portion (refer to 1361p in FIG. 9C) and the second penetrating portion (refer to 1362p in FIG. 9C).

For example, as shown in FIG. 9D, the barrier portion 139 may be formed to fill the second portion 1362. In this embodiment, the barrier portion 139 may also be formed on a bottom surface and lateral side surfaces of the first portion 1361. In an embodiment, as shown in FIG. 9E, in the first portion 1361, a hydrogen-containing portion 138 may then be formed by filling an insulating material containing hydrogen on the barrier portion 139.

In an embodiment, as shown in FIG. 9F, the second wiring portion 180 connected with the channel structure CH may then be formed.

According to an embodiment, the hydrogen-containing insulation portion 136 is in a portion where a portion of the base insulation layer 135a in the connection region is removed, and the insulation layer 134 including the base insulation portion 135 and the hydrogen-containing insulation portion 136 is formed in a portion where the gate contact portion 184 is disposed in the connection region. Accordingly, the semiconductor device 10 having excellent performance can be formed through an easy process, thereby increasing productivity.

In FIG. 9F, it is illustrated as an example that an upper surface of the hydrogen-containing insulation portion 136 is disposed on the same plane (e.g., in the Z-axis direction) as an upper surface of the channel structure CH, an upper surface of the dummy structure DH1, and upper surfaces of the gate contact portion 184 and the separation structure 146. This is according to an example of the manufacturing process. However, embodiments of the present disclosure are not necessarily limited thereto.

In some embodiments depending on manufacturing processes, the upper surface of the hydrogen-containing insulation portion 136, the upper surface of the channel structure CH, the upper surface of the dummy structure DH1, the upper surface of the gate contact portion 184, and the upper surface of the separation structure 146 may be disposed in any of various positions. For example, the upper surface of the hydrogen-containing insulation portion 136 may be disposed on a plane different from at least one of the channel structure CH, the dummy structure DH1, the gate contact portion 184 and the separation structure 146. In addition, the upper surfaces of at least two of the channel structure CH, the dummy structure DH1, the gate contact portion 184, and the separation structure 146 may be positioned on different planes from each other. Numerous other variations are possible.

Embodiments different from the above-described embodiments will be described in detail with reference to FIG. 10. For the same or similar reference numerals as the above-described embodiment, the description of the above-described embodiment may be applied as it is, except where otherwise noted. Hereinafter, description will be given mainly on parts different from the description in the above-described embodiment and a repeated description may be omitted for economy of description.

FIG. 10 is a schematic cross-sectional view of a semiconductor device 20 according to an embodiment.

Referring to FIG. 10, a semiconductor device 20 according to an embodiment may have a chip-to-chip (C2C) structure in which a semiconductor device 20 is bonded by a wafer bonding method. For example, a lower chip including a circuit region 200a formed on a first substrate 210a is prepared, an upper chip including a cell region 100a formed on a second substrate 110a is prepared, and then the lower chip and the upper chip are bonded to each other thereby manufacture the semiconductor device 20.

In an embodiment, the circuit region 200a may be provided with a first substrate 210a, a circuit element 220, a first wiring portion 230, a first wiring portion 230, and a first bonding structure 238 that is electrically connected with the first wiring portion 230 and disposed on a surface opposite to the cell region 100a. Regions other than the first bonding structure 238 on the surface opposite to the cell region 100a may be covered by a first insulation layer 232.

In an embodiment, the cell region 100a may be provided with a second substrate 110a, a gate stacking structure 120, a channel structure CH, a second wiring portion 180, a second bonding structure 194 electrically connected to the second wiring portion 180 and disposed on a surface opposite to the circuit region 200a. Regions other than the second bonding structure 194 may be covered by an insulation layer 196.

In an embodiment, the second substrate 110a may be a semiconductor substrate including a semiconductor material. For example, the second substrate 110a may be a semiconductor substrate formed of a semiconductor material, and may be a semiconductor substrate in which a semiconductor layer is formed on a base substrate. For example, in an embodiment, the second substrate 110a may be formed of single crystal or polysilicon, germanium, silicon-germanium, a silicon-on-insulator, or a germanium-on-insulator. In some embodiments, the second substrate 110a may be formed of a support member including an insulation layer or insulating material. In an embodiment, after bonding the cell region 100a to the circuit region 200a, the semiconductor substrate provided in the cell region 100a may be removed and the support member including the insulation layer or insulating material may be formed.

In an embodiment, the gate stacking structures 120 are sequentially stacked below the second substrate 110a (e.g., in the Z-axis direction), and thus the gate stacking structure 120 may be disposed with a vertically inverted structure as compared to an embodiment shown in FIG. 2. In addition, in an embodiment, the channel structure CH penetrating the gate stacking structure 12 may have a structure in which the channel structure shown is vertically inverted as compared to embodiments shown in FIG. 2 or FIG. 3. Accordingly, when viewed in cross-section, the channel structure CH may have an inclined side surface that decreases in width from the circuit region 200a towards the second substrate 110a. In addition, the channel pad 144 and the second wiring portion 180 disposed on the gate stacking structure 120 may be disposed adjacent to the circuit region 200a.

For example, in an embodiment, the first bonding structure 238 and/or the second bonding structure 194 may be formed of aluminum, copper, tungsten, or an alloy including them. For example, since the first and second bonding structures 238 and 194 contain copper, the cell region 100a and the circuit region 200a have copper-to-copper bonding (e.g., direct contact bonding).

In FIG. 10, it is illustrated as an example that the gate stacking structure 120 includes a plurality of gate stacking structures. However, embodiments of the present disclosure are not necessarily limited thereto and one gate stacking structure may be included in an embodiment. Except as otherwise noted, the description of the structure of the gate stacking structure 120 and channel structure CH described with reference to FIG. 1 to FIG. 3, FIG. 4A to FIG. 4H, FIG. 5 to FIG. 8, and FIG. 9A to FIG. 9F may be applied as it is. In FIG. 10, it is illustrated as an example that the electrical connection structure between the channel structure CH and the horizontal conductive layers 112 and 114 and/or second substrate 110a is the same as that shown in FIG. 2. However, embodiments of the present disclosure are not necessarily limited thereto, and the electrical connection structure between the channel structure CH and the horizontal conductive layers 112 and 114 and/or the second substrate 110a may be variously modified.

The semiconductor device 20 according to an embodiment may include an input/output pad and an input/output connection wire (not shown) electrically connected thereto. The input/output connection wire may be electrically connected with a portion of the second bonding structure 194. The input/output pad may be disposed, for example, on an insulation layer 198b covering an outer surface of the second substrate 110a. In some embodiments, a separate input/output pad electrically connected to the circuit region 200a may be provided.

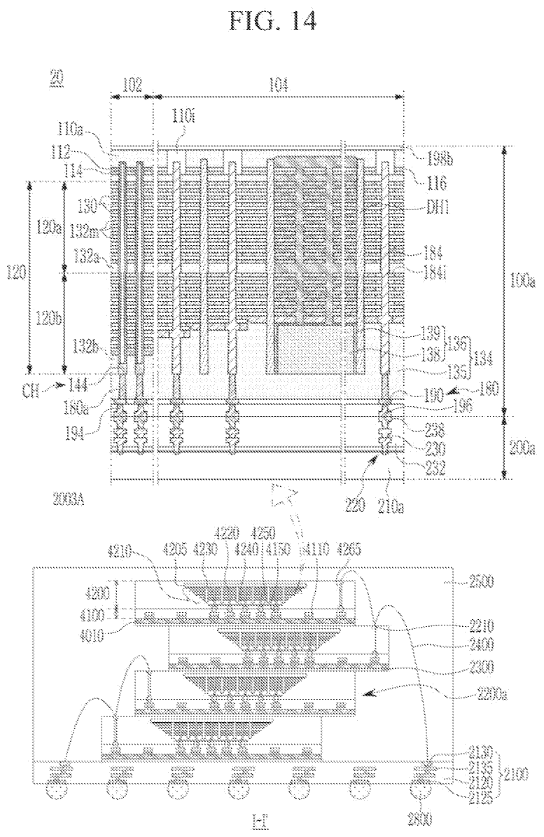

For example, the circuit region 200a and the cell region 100a each may be a portion corresponding to a first structure 1100F and a second structure 1100S of a semiconductor device 1100 included in an electronic system 1000 shown in FIG. 11. For example, the circuit region 200a and the cell region 100a may be regions including a first structure 4100 and a second structure 4200s of a semiconductor chip 2200a shown in FIG. 14.

An example of an electronic system including a semiconductor device, which is the same as the above-described semiconductor device will now be described in detail.

FIG. 11 schematically illustrates an electronic system including a semiconductor device according to an embodiment.

Referring to FIG. 11, an electronic system 1000 according to an embodiment may include a semiconductor device 1100 and a controller 1200 that is electrically connected with the semiconductor device 1100. In an embodiment, the electronic system 1000 may be a storage device including one or a plurality of semiconductor devices 1100 or an electronic device including the storage device. For example, in an embodiment, the electronic system 1000 may be a solid-state drive (SSD) device including one or a plurality of semiconductor devices 1100, a medical device, or a communication device. However, embodiments of the present disclosure are not necessarily limited thereto.

In an embodiment, the semiconductor device 1100 may be a non-volatile memory device, and, for example, may be a NAND flash memory device described with reference to FIG. 1 to FIG. 3, FIG. 5 to FIG. 8, FIG. 9A to FIG. 9F, and FIG. 10. The semiconductor device 1100 may include a first structure 1100F and a second structure 1100S disposed on the first structure 1100F. In an embodiment, the first structure 1100F may be disposed adjacent to the second structure 1100S. In an embodiment, the first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first upper line UL1 and a second gate upper line UL1 and UL2, first gate lower line LL1 and a second gate lower line and LL2, and a memory cell string CSTR between the bit line BL and the common source line CSL. However, embodiments of the present disclosure are not necessarily limited thereto.

In an embodiment, in the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may be variously modified and are not necessarily limited to those shown in FIG. 11.

In an embodiment, the lower transistors LT1 and LT2 may include ground selection transistors, and the upper transistors UT1 and UT2 may include string selection transistors. The first gate lower line LL1 and the second gate lower line LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

in an embodiment, the common source line CSL, the first and second gate lower lines LL1 and LL2, the word line WL, and the first and second gate upper lines UL1 and UL2 may be electrically connected with a decoder circuit 1110 through a first connection wire 1115 extending to the second structure 1100S from the first structure 1100F. The bit line BL may be electrically connected with a page buffer 1120 through a second connection wire 1125 extending to the second structure 1100S from the first structure 1100F.

In an embodiment, in the first structure 1100F, the decoder circuit 1110 and the page buffer 1120 may perform a control operation for at least one memory cell among the plurality of memory cell transistors MCT. The decoder circuit 1110 and the page buffer 1120 may be controlled by a logic circuit 1130. The semiconductor device 1100 may communicate with the controller 1200 through an input/output pad 1101 that is electrically connected with the logic circuit 1130. The input/output pad 1101 may be electrically connected with the logic circuit 1130 through an input/output connection wire 1135 extending to the second structure 1100S from the first structure 1100F.

In an embodiment, the controller 1200 may include a processor 1210, a NAND controller 1220, and a host interface 1230. In some embodiments, the electronic system 1000 may include a plurality of semiconductor devices 1100, and in this embodiment, the controller 1200 may control the plurality of semiconductor devices 1100.

The processor 1210 may control the overall operation of the electronic system 1000 including the controller 1200. In an embodiment, the processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be recorded in the memory cell transistor MCT of the semiconductor device 1100, data to be read from the semiconductor device 1100, or the like may be transmitted through the NAND interface 1221. The host interface 1230 may provide a communication function between the electronic system 1000 and an external host. When receiving a control command from the external host through the host interface 1230, the processor 1210 may control the semiconductor device 1100 responding to the control command.

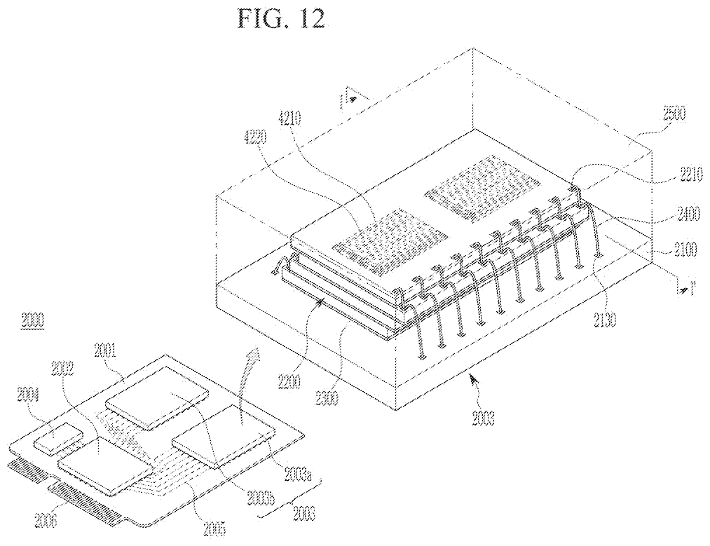

FIG. 12 schematically illustrates an electronic system including a semiconductor device according to an embodiment.

Referring to FIG. 12, an electronic system 2000 according to an embodiment may include a main substrate 2001, a controller 2002 mounted on the main substrate 2001, one or more semiconductor packages 2003, and a DRAM 2004. The semiconductor package 2003 and the DRAM 2004 may be connected with the controller 2002 by a wiring pattern 2005 formed in the main substrate 2001.

In an embodiment, the main substrate 2001 may include a connector 2006 including a plurality of pins combined with the external host. The number and arrangement of the plurality of pins in the connector 2006 may vary depending on a communication interface between the electronic system 2000 and the external host. In an embodiment, the electronic system 2000 may communicate with the external host through one of interfaces such as a universal serial bus (USB), a peripheral component interface (PCI)-express, a serial advanced technology attachment (ADTA), M-Phy for a universal flash storage (UFS), or the like. In an embodiment, the electronic system 2000 may operate by power supplied from the external host through the connector 2006. The electronic system 2000 may further include a power management integrated circuit (PMIC) that distribute power supplied from the external host to the controller 2002 and the semiconductor package 2003.

The controller 2002 may record data to the semiconductor package 2003 or read data from the semiconductor package 2003, and may increase the operation speed of the electronic system 2000.

In an embodiment, the DRAM 2004 may be a buffer memory for mitigating a speed difference between the semiconductor package 2003, which is a data storage space, the external host. The DRAM 2004 included in the electronic system 2000 may operate as one of cache memory, and may provide a space for temporarily storing data in the control operation for the semiconductor package 2003. In an embodiment, in which the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may be respectively semiconductor packages including a plurality of semiconductor chips 2200. Each of the first semiconductor package 2003a and the second semiconductor package 2003b may include a package substrate 2100, a semiconductor chip 2200 on the package substrate 2100, an adhesive layer 2300 disposed on a bottom surface of each of the semiconductor chips 2200, a connection structure 2400 that electrically connects the semiconductor chip 2200 and the package substrate 2100, and a molding layer 2500 that covers the semiconductor chip 2200 and the connection structure 2400 on the package substrate 2100.

In a embodiment, the package substrate 2100 may be a printed circuit board including a package upper pad 2130. Each semiconductor chip 2200 may include an input/output pad 2210. The input/output pad 2210 may correspond to the input/output pad 1101 of FIG. 6. Each semiconductor chip 2200 may include a gate stacking structure 3210 and a channel structure 3220. The semiconductor chip 2200 may include the semiconductor device described with reference to FIG. 1 to FIG. 3, FIG. 4A to FIG. 4H, FIG. 5 to FIG. 8, FIG. 9A to FIG. 9F, and FIG. 10.

In an embodiment, the connection structure 2400 may be a bonding wire that electrically connects the input/output pad 2210 and the package upper pad 2130. Thus, in each of the first semiconductor package 2003a and the second semiconductor package 2003b, the semiconductor chips 2200 may be electrically connected with each other through a bonding wire method, and may be electrically connected with the package upper pad 2130 of the package substrate 2100. In some embodiments, in each of the first semiconductor package 2003a and the second semiconductor package 2003b, the semiconductor chips 2200 are electrically connected to each other by a connection structure including a through electrode (e.g., a Through Silicon Via) instead of the connection structure 2400 of the bonding wire type.

In an embodiment, the controller 2002 and the semiconductor chip 2200 may be included in a single package. For example, the controller 2002 and the semiconductor chip 2200 are mounted on a separate interposer substrate that is different from the main substrate 2001, and the controller 2002 and the semiconductor chip 2200 may be connected with each other by a wire formed in the interposer substrate.

FIG. 13 and FIG. 14 are schematic cross-sectional views of semiconductor packages according to embodiments. FIG. 13 and FIG. 14 each describes an embodiment of the semiconductor package 2003 of FIG. 12, and conceptually illustrates a region cut along the line I-I′ of the semiconductor package 2003 of FIG. 12.

Referring to FIG. 13, in a semiconductor package 2003, a package substrate 2100 may be a printed circuit board. The package substrate 2100 may include a package substrate body portion 2120, a package upper pad 2130 disposed on an upper surface of the package substrate body portion 2120, a lower pad 2125 disposed on a bottom surface of the package substrate body portion 2120 or exposed through the bottom surface, and an internal wire 2135 that electrically connects the upper pad 2130 and the lower pad 2125 in the package substrate body portion 2120. The upper pad 2130 may be electrically connected with the connection structure 2400. The lower pad 2125 may be connected to the wiring pattern 2005 of the main substrate 2010 of the electronic system 2000 as shown in FIG. 7 through a conductive connection portion 2800.

In an embodiment, each semiconductor chip 2200 may include a semiconductor substrate 3010, and a first structure 3100 and a second structure 3200 that are sequentially stacked (e.g., in the Z-axis direction) on the semiconductor substrate 3010. The first structure 3100 may include a peripheral circuit region including a peripheral wire 3110. In an embodiment, the second structure 3200 may include a common source line 3205, a gate stacking structure 3210 on the common source line 3205, a channel structure 3220 and a separation structure 3230 that penetrate the gate stacking structure 3210, a bit line 3240 electrically connected with the channel structure 3220, and a gate connection wire electrically connected with a word line (refer to WL in FIG. 11) of the gate stacking structure 3210.

In the semiconductor chip 2200 or semiconductor device according to an embodiment, a hydrogen-containing insulation portion 136 may be provided to increase performance of the semiconductor chip 2200 or semiconductor device.

Each semiconductor chip 2200 may include a penetration wire 3245 that is electrically connected with the periphery wire 3110 of the first structure 3100 and extends into the second structure 3200. The penetration wire 3245 may penetrate the gate stacking structure 3210 and may be further disposed outside the gate stacking structure 3210. Each semiconductor chip 2200 may further include an input/output connection wire 3265 electrically connected with the peripheral wire 3110 of the first structure 3100 and extending into the second structure 3200, and an input/output pad 2210 electrically connected with the input/output connection wire 3265.

In an embodiment, a plurality of semiconductor chips 2200 in the semiconductor package 2003 may be electrically connected to each other by the connection structure 2400 in the form of a bonding wire. As another example, the plurality of semiconductor chip 2200 or a plurality of parts forming the same may be electrically connected by a connection structure including a through electrode.

Referring to FIG. 14, in a semiconductor package 2003A, each semiconductor chip 2200a may include a semiconductor substrate 4010, a first structure 4100 on the semiconductor substrate 4010, and a second structure 4200 bonded with the first structure 4100 on the first structure 4100 by a wafer bonding method.

In an embodiment, the first structure 4100 may include peripheral circuit region including a peripheral wire 4110 and a first bonding structure 4150. The second structure 4200 may include a common source line 4205, a gate stacking structure 4210 disposed between the common source line 4205 and a first structure 4100, a channel structure 4220 and a separation structure 4230 that penetrate the gate stacking structure 4210, and a second bonding structure 4250 that is electrically connected with a word line (refer to WL in FIG. 11) of the gate stacking structure 4210. For example, in an embodiment, the second bonding structure 4250 may be electrically connected to the channel structure 4220 and the word line WL through a bit line 4240 electrically connected with the channel structure 4220 and a gate connection wire electrically connected to the word line WL. The first bonding structure 4150 of the first structure 4100 and the second bonding structure 4250 of the second structure 4200 may be bonded to each other, while directly contacting each other. In an embodiment, a bonding portion of the first bonding structure 4150 and the second bonding structure 4250 may be formed of, for example, copper (Cu). However, embodiments of the present disclosure are not necessarily limited thereto and the material of the bonding portion may vary.

In the semiconductor chip 2200 or semiconductor device according to an embodiment, a hydrogen-containing insulation portion 136 may be provided to increase performance of the semiconductor chip 2200 or semiconductor device.

Each semiconductor chip 2200a may further include an input/output pad 2210 and input/output connection wire 4265 disposed below the input/output pad 2210. The input/output connection wire 4265 may be electrically connected to a portion of the second bonding structure 4250.

In an embodiment, a plurality of semiconductor chips 2200a in a semiconductor package 2003A may be electrically connected to each other by a connection structure 2400 in the form of a bonding wire. As another example, the plurality of semiconductor chips 2200 or a plurality of portions forming the plurality of semiconductor chips 2200 may be electrically connected by a connection structure including a penetration electrode.

Embodiments of the present disclosure have been described in detail above. However, the scope of the present disclosure is not limited thereto. Numerous variations to the described embodiments of the present disclosure may be made by a person of an ordinary skill in the art and also fall within the scope of the present disclosure.

What is claimed is:

1. A semiconductor device including a cell array region and a connection region, comprising:
a gate stacking structure that includes a plurality of gate electrodes and a plurality of interlayer insulation layers that are alternately stacked, the gate stacking structure extends in a first direction and is separated by a plurality of separation structures in a second direction that crosses the first direction;
a channel structure penetrating the gate stacking structure in the cell array region;
a plurality of gate contact portions penetrating the gate stacking structure in the connection region, the plurality of gate contact portions are electrically connected to the plurality of gate electrodes, respectively; and
an insulation layer that is provided separately from the separation structure, the insulation layer covering at least the gate stacking structure,
wherein the insulation layer comprises a base insulation portion and a hydrogen-containing insulation portion, and
the hydrogen-containing insulation portion includes a hydrogen-containing portion having a different material from a material of the base insulation portion, the hydrogen-containing portion including hydrogen.

2. The semiconductor device of claim 1, wherein the hydrogen-containing portion includes a silicon nitride containing hydrogen.

3. The semiconductor device of claim 1, wherein the base insulation portion includes a silicon oxide, a silicon oxynitride, a material with lower permittivity than silicon oxide, or a combination thereof.

4. The semiconductor device of claim 1, wherein the hydrogen-containing insulation portion is disposed in the connection region and is not disposed in the cell array region.

5. The semiconductor device of claim 1, wherein:
the hydrogen-containing insulation portion has a width larger than a width of at least one of the plurality of separation structures; or
the hydrogen-containing insulation portion includes a portion between the plurality of separation structures.

6. The semiconductor device of claim 1, wherein, a width of at least a portion of the hydrogen-containing insulation portion in the second direction is greater than or equal to about 50% of a width between the plurality of separation structures in the second direction.

7. The semiconductor device of claim 1, further comprising a dummy structure penetrating the insulation layer and the gate stacking structure in the connection region,
wherein the hydrogen-containing insulation portion has a larger width than a width of the dummy structure.

8. The semiconductor device of claim 1, wherein, in the second direction, at least a portion of the hydrogen-containing insulation portion is disposed over a region where the plurality of gate contact portions are disposed, a region where a plurality of dummy structures are disposed, or a region where at least one of the plurality of gate contact portions and at least one of the plurality of dummy structures are disposed.

9. The semiconductor device of claim 1, wherein the hydrogen-containing insulation portion is disposed between adjacent separation structures among the plurality of separation structures in the second direction.

10. The semiconductor device of claim 1, wherein the hydrogen-containing insulation portion passes through at least one of the plurality of separation structures and is disposed over a plurality of memory cell blocks in the second direction.

11. The semiconductor device of claim 1, wherein:
a plurality of pad regions that the plurality of gate electrodes and the plurality of gate contact portions are respectively connected thereto are disposed in the connection region;
the pad region comprises a first pad portion having a first length in the first direction and a second pad portion having a second length greater than the first length in the first direction; and
the hydrogen-containing insulation portion includes a body portion in the second pad portion.

12. The semiconductor device of claim 11, wherein the hydrogen-containing insulation portion further comprises an extension portion extending in the first direction in the first pad portion and having a width that is less than a width of the body portion.

13. The semiconductor device of claim 1, wherein the hydrogen-containing insulation portion comprises:
a first portion on the gate stacking structure; and
a second portion including a penetrating portion penetrating the gate stacking structure and a horizontal portion disposed between the plurality of gate electrodes.

14. The semiconductor device of claim 13, wherein:
the hydrogen-containing portion is disposed in the first portion; and
the hydrogen-containing insulation portion further includes a barrier portion forming the second portion and having a material different from the material of the hydrogen-containing portion.

15. The semiconductor device of claim 14, wherein:
the barrier portion is disposed on a bottom surface and lateral side surfaces of the first portion; and
the hydrogen-containing portion is disposed on the barrier portion in the first portion.

16. A semiconductor device including a cell array region and a connection region, comprising:
a gate stacking structure that includes a plurality of gate electrodes and a plurality of interlayer insulation layers that are alternately stacked;
a channel structure penetrating the gate stacking structure in the cell array region; and
an insulation layer that is disposed in the connection region and covering at least the gate stacking structure,
the insulation layer comprises a hydrogen-containing insulation portion including a hydrogen-containing portion having a material that is different from an insulating material disposed in the cell array region, the hydrogen-containing portion containing hydrogen, and a base insulation portion including a material that is different from the material of the hydrogen-containing portion.

17. The semiconductor device of claim 16, wherein the hydrogen-containing portion includes a silicon nitride containing hydrogen.

18. The semiconductor device of claim 16, wherein the base insulation portion includes a silicon oxide, a silicon oxynitride, a material with lower permittivity than silicon oxide, or a combination thereof.

19. The semiconductor device of claim 16, wherein the hydrogen-containing insulation portion is disposed between adjacent separation structures of the plurality of separation structures in the second direction, or passes through at least one of the plurality of separation structures and is disposed over a plurality of memory cell blocks in the second direction.

20. An electronic system comprising:
a main substrate;
a semiconductor device on the main substrate; and
a controller that is electrically connected with the semiconductor device on the main substrate,
wherein the semiconductor device comprises a cell array region and a connection region,
the semiconductor device comprises:
a gate stacking structure that includes a plurality of gate electrodes and a plurality of interlayer insulation layers that are alternately stacked, the gate stacking structure extends in a first direction and is separated by a plurality of separation structures in a second direction that crosses the first direction;
a channel structure penetrating the gate stacking structure in the cell array region;
a plurality of gate contact portions penetrating the gate stacking structure in the connection region, the plurality of gate contact portions are electrically connected to the plurality of gate electrodes, respectively; and
an insulation layer that is provided separately from the separation structure, the insulation layer covering at least the gate stacking structure, and
the insulation layer comprises a base insulation portion and a hydrogen-containing insulation portion, and
the hydrogen-containing insulation portion includes a hydrogen-containing portion having a different material from a material of the base insulation portion, the hydrogen-containing portion including hydrogen.
